(19) United States
(12) Patent Application Publication
(10) Pub. No.: US 2016/0260919 A1
(43) Pub. Date: Sep. 8, 2016

(54) Photovoltaic Systems and Spray Coating Processes for Producing Photovoltaic Systems

(71) Applicant: PPG Industries Ohio, Inc., Cleveland, OH (US)

(72) Inventors: Maurizio Ballarino, Limbiate (IT); Francesca Brunetti, Rome (IT); Michela Cagliani, Milan (IT); Giorgio Cardone, Milan (IT); Aldo Di Carlo, Rome (IT); Giuseppina Polino, Salerno (IT)

(21) Appl. No.: 15/152,936

(22) Filed: May 12, 2016

Related U.S. Application Data
(63) Continuation-in-part of application No. PCT/US2014/065227, filed on Nov. 12, 2014.
(60) Provisional application No. 61/902,836, filed on Nov. 12, 2013.

(51) Int. Cl. H01L 51/42; H01L 51/00; H01L 51/44

(52) U.S. Cl. CPC H01L 51/4253; H01L 51/441; H01L 51/0021; H01L 51/0003; H01L 2251/303; H01L 2251/301; H01L 51/0034; H01L 51/0037; H01L 51/0036; H01L 51/0047; H01L 51/0043

(57) ABSTRACT

Photovoltaic systems and processes for producing photovoltaic systems are disclosed.

### CROSS-REFERENCE TO RELATED APPLICATIONS

This patent application is a continuation-in-part of prior co-pending International Patent Application No. PCT/US2014/065227, filed on Nov. 12, 2014, and claims the benefit of the filing date of International Patent Application No. PCT/US2014/065227 under 35 U.S.C. §365(c). This patent application and International Patent Application No. PCT/US2014/065227 claim priority to U.S. Provisional Patent Application No. 61/902,836, filed on Nov. 12, 2013.

International Patent Application No. PCT/US2014/065227 and U.S. Provisional Patent Application No. 61/902,836 are incorporated by reference into this specification.

### TECHNICAL FIELD

The present invention generally relates to organic photovoltaic systems and processes for producing organic photovoltaic systems. This specification also relates to low work function electrodes for photovoltaic systems and processes for producing low work function electrodes for photovoltaic systems.

### BACKGROUND

Photovoltaic (PV) systems convert electromagnetic energy into electrical energy. Photovoltaic systems can be categorized based on the architecture of the devices and the materials of construction. Organic photovoltaic systems comprise an organic photoelectric active material. The organic photoelectric active material typically comprises a semiconducting organic polymer and a fullerene compound. When the semiconducting organic polymer comes into contact with incident light in or near the visible part of the electromagnetic spectrum, delocalized π electrons are excited by the electromagnetic energy from the polymer molecule's highest occupied molecular orbital (HOMO) to the lowest unoccupied molecular orbital (LUMO).

The photo-excitation of electrons in the semiconducting organic polymer causes the formation of excitons comprising electron-hole pairs at the LUMO energy level. The semiconducting organic polymer functions as an electron donor and provides a conductive network for transporting holes after the dissociation of the excitons. The fullerene compound functions as an electron acceptor and provides a conductive network for transporting the excited electrons after dissociation from the holes. The effectiveness and efficiency of organic photovoltaic systems at generating electricity depends in part on the ability of the systems to extract the excited and dissociated electrons from the photoelectric active material. This generally requires that adjacent electrodes (functioning as cathodes, i.e., the electron-accepting electrodes) have a work function that is sufficiently low to collect the excited and dissociated electrons from the LUMO energy level of the photoelectric active material.

Conventional low work function electrodes and electron transport materials such as alkaline earth metals (e.g., Ca, Mg) and metal oxides (e.g., ZnO, In₂O₃) are disadvantageous in organic photovoltaic systems for various reasons. For instance, alkaline earth metals are highly chemically reactive and readily oxidize upon exposure to ambient air and other relatively benign oxidizing agents. Alkaline earth metals and metal oxide layers also generally require complex deposition techniques to form the relatively thin layers (generally less than 1-micrometer and often less than 100-nanometers) characteristic of organic photovoltaic systems. These complex and often specialized deposition techniques limit the ability to produce large-area organic photovoltaic systems.

### SUMMARY

The present invention aims to address all or at least some of the aforementioned deficiencies of the prior art. In particular it aims to provide efficient and robust low work function electrodes produced by commercially applicable deposition techniques, which provide for the production of organic photovoltaic systems by processes compatible with the requirements of large scale, high throughput mass production. These objectives are attained by the low work function electrode, the photovoltaic system, and the processes for the production of these as described in the following.

The present invention thus relates to a process for producing a low work function electrode for a photovoltaic system, which comprises depositing an electrode layer over a substrate. An ethoxylated polyethyleneimine (PEIE) layer is spray coated over the electrode layer. An optional metal oxide nanoparticle layer may be deposited over the electrode layer and the PEIE layer spray coated over the metal oxide nanoparticle layer. A low work function electrode for a photovoltaic system produced by this process is also within the scope of the present invention.

Moreover, the present invention is directed towards a process for producing a photovoltaic system, which comprises depositing a first electrode layer onto a substrate. An ethoxylated polyethyleneimine (PEIE) layer is spray coated onto the first electrode layer. An optional metal oxide nanoparticle layer may be deposited over the first electrode layer and the PEIE layer spray coated over the metal oxide nanoparticle layer. A bulk heterojunction active layer is deposited onto the PEIE layer. A hole transport layer and/or a second electrode layer is deposited onto the bulk heterojunction active layer. A photovoltaic system produced by this process is also within the scope of the present invention.

It is understood that the invention disclosed and described in this specification is not limited to just the aspects summarized in this Summary and can include additional aspects described below.

### BRIEF DESCRIPTION OF THE DRAWINGS

Some aspects of the systems and processes described in this specification can be better understood by reference to the accompanying figures, in which:

FIG. 1 is a flowchart diagram illustrating a bottom up process for producing a photovoltaic system according to the present invention, wherein the order of the bottom up deposition steps reads from the top down in the diagram;

FIG. 2 is a flowchart diagram illustrating a bottom up process for producing a photovoltaic system according to the present invention, wherein the order of the bottom up deposition steps reads from the top down in the diagram;

FIG. 3 is a flowchart diagram illustrating a bottom up process for producing a photovoltaic system according to the present invention, wherein the order of the bottom up deposition steps reads from the top down in the diagram;

FIG. 4 is a schematic diagram illustrating a photovoltaic system according to the present invention produced in accordance with the process illustrated in FIG. 1;

FIG. 5 is a schematic diagram illustrating a photovoltaic system according to the present invention produced in accordance with the process illustrated in FIG. 2;

FIG. 6 is a schematic diagram illustrating a photovoltaic system according to the present invention produced in accordance with the process illustrated in FIG. 3;

FIG. 7 is a schematic diagram illustrating another photovoltaic system according to the present invention;

FIG. 8 is a flowchart diagram illustrating a bottom up process for producing a photovoltaic system according to the present invention, wherein the order of the bottom up deposition steps reads from the top down in the diagram; and

FIG. 9 is a schematic diagram illustrating a photovoltaic system according to the present invention produced in accordance with the process illustrated in FIG. 8.

The reader will appreciate the foregoing details, as well as others, upon considering the following detailed description of the processes and systems according to this specification.

### DESCRIPTION

As described in this specification the present invention is directed to processes for producing low work function electrodes for organic photovoltaic systems, such as, for example, polymer-fullerene bulk heterojunction organic photovoltaic systems. The processes may comprise depositing an electrode layer onto a substrate and spray coating an ethoxylated polyethyleneimine (PEIE) layer over the electrode layer. An optional metal oxide nanoparticle layer (e.g., a zinc oxide nanoparticle layer) may be deposited (e.g., spray coated) over the electrode layer and the PEIE layer spray coated over the metal oxide nanoparticle layer. This multi-layer spray coating process avoids the functional surface area constraints imposed by other deposition techniques, such as spin coating, for example, and may be used to produce large-area organic photovoltaic systems with relatively high through-put.

As used in this specification, including the claims, the term “work function” refers to the minimum energy required to remove an electron from a solid material to a point immediately adjacent to the solid material surface. In the active material of an organic photovoltaic system, a photo-excited electron dissociated from its corresponding hole in the semiconducting polymer occupies the LUMO energy level of the acceptor material (e.g., a fullerene compound). Therefore, the work function of the cathode in an organic photovoltaic system must be sufficiently low in order to approximate the LUMO energy level of the acceptor material and extract/collect the electron from the active material. On the other hand, the work function of the anode in an organic photovoltaic system must be relatively higher than the work function of the cathode to provide the driving force for exciton dissociation, transport, and the extraction/collection of holes.

The cathodes and anodes in organic photovoltaic systems are generally comprised of different materials having different work functions. Electrodes must also be sufficiently conductive to establish an electric current. Many conductive metals such as silver and conductive polymers such as blends of poly(3,4-ethylenedioxythiophene):poly(styrene sulfonate) (PEDOT:PSS) possess the necessary intrinsic electrical conductivity, but the intrinsic work function of such materials is too high to function effectively as a cathode in organic photovoltaic systems. The processes described in this specification address and overcome these problems by spray coating an ethoxylated polyethyleneimine (PEIE) layer over an electrode layer to reduce the work function of the electrode layer, thereby making the electrode material suitable for use as a cathode in an organic photovoltaic system. The processes described in this specification optionally comprise depositing a metal oxide nanoparticle layer (e.g., a zinc oxide nanoparticle layer) over the electrode layer and spray coating the PEIE layer over the metal oxide nanoparticle layer. In some examples, the metal oxide nanoparticle layer may be spray coated over the electrode layer. In this manner, the anode in an organic photovoltaic system may comprise a material such as, for example, silver or a PEDOT:PSS-based polymeric composition, and the corresponding cathode may comprise the same material or a different material with a spray-coated PEIE layer, and optional metal oxide nanoparticle layer, located between and contacting the cathode and the active material, wherein the metal oxide nanoparticle and/or PEIE layers lower the work function of the cathode.

Ethoxylated polyethyleneimine (PEIE) is a highly branched copolymer comprising primary and secondary amino groups and having the following general chemical structure:

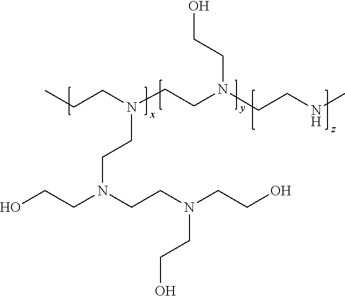

wherein x, y, and z indicate the repeating units of the copolymer. PEIE functions as a surface modifier, reducing the work function of an electrode when applied to the surface of the electrode. Without intending to be bound by any theory, it is believed that the amine groups in PEIE molecules are primarily involved in surface interactions with electrode material, giving rise to interface dipoles that reduce the work function but do not change the electrical transmittance between the active material and a PEW-modified electrode in an organic photovoltaic system.

The work function modifying properties of PEIE are described, for example, in Zhou et al., Science, vol. 336, pp. 327-332 (2012) and International Patent Application Publication No. WO 2012/166366 A1, both of which are incorporated by reference into this specification. These references disclose spin coating PEIE layers onto electrode surfaces. Spin coating is a batch process requiring the use of specialized equipment that spins the deposition substrate to spread the coating material by centrifugal force. Spin coating therefore severely limits the surface area over which material may be deposited and the rate of photovoltaic device production. The processes described in this specification employ spray coating techniques to deposit PEIE layers and preferably also other layers comprising photovoltaic systems according to the present invention. Spray coating avoids the functional surface area constraints imposed by other deposition techniques such as spin coating. Spray coating may also be used to produce large-area organic photovoltaic systems with relatively high through-put, making the processes described in this specification useful for the mass production of photovoltaic systems at higher rates, for example, using roll-to-roll processes.

As used in this specification, including the claims, “spray coating” refers to a coating process comprising atomizing or aerosolizing a liquid coating composition in a compressed gas stream functioning as a carrier medium that propels the coating composition, targeting the carrier gas comprising the coating composition into contact with a substrate, and depositing the coating composition from the carrier gas stream onto the substrate forming a coating layer. As used in this specification, including the claims, “spray coating” also includes electro-spray coating in which a liquid coating composition is atomized or aerosolized and propelled into contact with a substrate (where the coating composition deposits onto the substrate forming a coating layer) using electrical charge as the driving mechanism, with or without a gaseous carrier medium. The spray coating of PEIE layers and optionally other layers comprising a photovoltaic system may be performed manually using a hand-held spray gun or automated using a computer-controlled robotic spray coating system.

According to the present invention, a PEIE layer may be spray coated onto the surface of an electrode to be located adjacent to the photoelectric active material in an organic photovoltaic system. The PEIE material may be spray coated using an aqueous solution, or an alcohol-based solution, and dried to form a layer having a dry film thickness in the range of 1 nanometer to 50 nanometers, or any sub-range subsumed therein, such as, for example, 10-30 nanometers or 10-20 nanometers. The thickness and density of a spray coated PEIE layer may be controlled by setting the spray coating process parameters, including the geometry of the spraying nozzle, the distance between the spray nozzle and the electrode surface, the composition of the carrier gas (e.g., air, nitrogen, argon, and the like), the flow rate of the carrier gas, the pressure of the carrier gas, the temperature of the electrode surface target, the temperature of the PEIE coating solution, the composition of the PEIE coating solution (e.g., solvent composition, PEIE concentration, and the like), the lateral trajectory of the spray nozzle, the duration of the spray contact with the electrode target, and the number of spray coats applied to the electrode target. The process parameters used to achieve a PEIE layer of specified thickness and density may depend on the surface texture properties of the adjacent layer onto which the PEIE layer is deposited.

A PEIE layer may for example be spray coated in accordance with the present invention using an aqueous and/or alcohol-based formulation comprising 0.10% to 10.00% PEIE by weight based on the total weight of the formulation, or any sub-range subsumed therein, such as, for example 0.40-5.00% by weight based on the total weight of the formulation. The aqueous formulation may be substantially free of alcohols such as methoxyethanol, which means that such compounds, if present at all, are present in the aqueous formulation at no greater than incidental impurity levels. The aqueous formulation used for spray coating a PEIE layer according to the present invention may include a non-toxic alcohol co-solvent or additive such as, for example, ethanol or isopropanol. An aqueous formulation for spray coating a PEIE layer used in accordance with the present invention may consist of PEIE and water. Alternatively, an aqueous and/or alcohol-based formulation for spray coating a PEIE layer may consist of PEIE, water, and isopropanol, for example, or may consist of PEIE, water, and ethanol, for example.

According to the present invention an electrode layer may be spray coated onto a substrate and a PEIE layer may be spray coated onto the electrode layer to produce a low work function electrode for a photovoltaic system. For example, an electrode layer comprising a conductive polymer may be spray coated onto a substrate. A formulation comprising poly(3,4-ethylenedioxythiophene):poly(styrene sulfonate) (PEDOT:PSS) may be spray coated onto a substrate to produce a PEDOT:PSS-based polymeric electrode layer. The PEDOT:PSS-containing formulation may, for example, be spray coated using an aqueous dispersion and dried to form a layer having a dry film thickness in the range of 150 nanometers to 250 nanometers, or any sub-range subsumed therein, such as, for example, 180-230 nanometers. PEDOT:PSS-based polymeric electrodes exhibit an intrinsic work function of about 4.96±0.06 eV. A PEDOT:PSS-based polymeric electrode layer having a spray coated PEIE layer on a surface of the electrode layer may exhibit a reduced work function of about 3.58±0.06 eV.

The PEDOT:PSS-based polymeric electrode layer may, for example, be formed by spray coating an aqueous dispersion formulation comprising poly(3,4-ethylenedioxythiophene); poly(styrene sulfonate); and one or more than one of ethylene glycol or dimethyl sulfoxide. This formulation is referred to herein as “PEDOT:PSS PH1000.” The PEDOT:PSS PH1000 formulation may, for example, comprise 1.0% to 1.3% solids content by weight, based on the total weight of the formulation, and a PEDOT:PSS ratio of 1:2.5 by weight. PEDOT:PSS formulations without ethylene glycol or dimethyl sulfoxide may be obtained, for example, from Heraeus Conductive Polymers under the trade name CLEVIOS. For example, without being limited thereto, 4-8% by weight ethylene glycol and/or dimethyl sulfoxide, based on total weight of the formulation, may be added to such commercially available formulations to produce PEDOT:PSS PH1000 formulations that may be used in accordance with the present invention.

According to the present invention also metallic layers and in particular silver layers can be used as electrode layers. For example, a silver layer may be spray coated onto a substrate to produce a silver electrode layer. Metallic silver layers may be spray coated in accordance with a Tollens' reaction in which silver nitrate in an aqueous ammonia solution is reduced to silver metal during the spraying by reaction with an aldehyde-containing compound. The spray coating of metallic silver layers is generally described, for example, in European Patent Publication Nos. 0 346 954 A2 and 1 469 099 A1, which are both incorporated by reference into this specification. An aqueous ammonia and silver nitrate solution may be loaded into a first chamber of a dual-spray gun, and an aqueous solution of an aldehyde-containing compound may be loaded into a second chamber of the dual-spray gun. The two solutions are then mixed immediately before exiting the spray gun and the reagents react during the spray deposition process, thereby forming a silver layer on a target substrate from the reaction products of the Tollens' reaction. A spray coated silver electrode layer may, for example, have a dry film thickness in the range of 50 nanometers to 150 nanometers, or any sub-range subsumed therein, such as, for example, 50-75 nanometers. Metallic silver exhibits an intrinsic work function of about 4.60±0.06 eV. A silver electrode layer having a spray coated PEIE layer on a surface of the electrode layer may exhibit a reduced work function of about 3.70±0.06 eV.

According to the present invention, an electrode layer may comprise a layer of dielectric material comprising metallic particles embedded in the dielectric material. For example, an electrode layer may comprise a polyurethane-based clear coat composition comprising micron-scale or nano-scale metallic particles embedded in the cured clear coat composition. The metallic particles may comprise copper particles, gold particles, platinum particles, and/or silver particles, for example. The metallic particles may comprise a core-shell structure comprising a copper core particle encapsulated with a silver shell layer. By way of example, copper-silver core-shell particles having a mean particle size of about 5-15 micrometers (for example, 12 micrometers) may be mixed into the resin component of a two-component urethane clear coating composition such as D8122 available from PPG Industries, Inc. The particles may be added to the resin component at a concentration of 40% to 60% by weight (for example, 50%) and stirred for a period of time, such as, for example, 10 minutes, to ensure that the particles are dispersed in the resin component. The resin component having dispersed particles may be mixed with a hardener component and, optionally, diluted with a solvent or reactive diluent to a viscosity suitable for spray coating of an electrode layer comprising metallic particles embedded in a cured dielectric material (14-16 dyn-second per square centimeter, for example). The curing conditions (temperature, time, and the like) of the spray coated electrode will depend on the particular dielectric material used. Suitable dielectric materials include, for example, cured polymer clear-coats such as acrylic, urethane, and epoxy based formulations.

As described above, a PEIE layer is spray coated over the electrode layer. The present invention also includes an optional metal oxide nanoparticle layer spray coated or otherwise deposited over the electrode layer, wherein the PEIE layer is spray coated over the deposited metal oxide nanoparticle layer. The metal oxide nanoparticle layer may be deposited by spray coating the electrode layer with a formulation comprising the metal oxide nanoparticles. For example, aqueous or alcohol-based (e.g., ethanol- or isopropanol-based) dispersions of metal oxide nanoparticles can be spray coated over the electrode layer and annealed (e.g., at temperatures ranging from 75° C. to 150° C., or any subrange subsumed therein, such as, for example, 100-120° C.) to drive off the dispersion solvent and form a deposited metal oxide nanoparticle layer. The metal oxide nanoparticles may have an average particle size of 5-100 nanometers, or any subrange subsumed therein, such as, for example, 10-50 nanometers, 10-25 nanometers, or 10-15 nanometers. The deposited metal oxide nanoparticle layer may have a dry film thickness of 10-125 nanometers, or any subrange subsumed therein, such as, for example, 10-50 nanometers, 10-25 nanometers, 10-15 nanometers, or 12-15 nanometers. In some examples of the invention, the metal oxide nanoparticles may comprise zinc oxide nanoparticles.

The electrode and PEIE layers (and optional metal oxide nanoparticle layer) may be respectively deposited onto a surface of any substrate that is or can be exposed to sunlight, such as, for example, buildings, vehicles, modular panels, photovoltaic device substrates, and the like. The spray coating techniques used in the processes according to the present invention enable the production of photovoltaic coating systems comprising a stack of spray coated layers, including an electrode layer and a PEIE layer (and an optional metal oxide nanoparticle layer), that together form a functional photovoltaic system deposited onto any convenient or suitable substrate. The substrate may, for example, comprise an electrically insulating dielectric layer that may be deposited onto an underlying substrate material to provide a homogenous and continuous base layer that is electrically, chemically, and mechanically inert to the overlying functional photovoltaic layers. The dielectric layer may provide a non-porous and relatively planar base layer. Typically the dielectric base layer, if present, has a surface roughness of less than 25 nanometers (Ra), preferably of less than 20 nanometers (Ra), more preferably of less than 15 nanometers (Ra), even more preferably of less than 10 nanometers (Ra), or less than 5 nanometers (Ra).

Such optionally present inert, non-porous, and relatively planar dielectric layer may, for example, comprise a cured acrylic urethane clear-coat layer. As used herein the term “cured,” refers to the condition of a liquid coating composition in which a film or layer formed from the liquid coating composition is at least tack free to touch. As used herein, the terms “cure” and “curing” refer to the progression of a liquid coating composition from the liquid state to a cured state and encompass physical drying of coating compositions through solvent or carrier evaporation (e.g., thermoplastic coating compositions) and/or chemical crosslinking of components in the coating compositions (e.g., thermosetting coating compositions). An example of a suitable acrylic urethane clear-coating composition that may be used to form a dielectric layer on a substrate is the D8109 UHS Clearcoat available from PPG Industries, Inc. As an example, an epoxy primer composition may be used to form an epoxy primer layer on a substrate, and an acrylic urethane clear-coating composition may be used to form a dielectric layer deposited on the underlying epoxy primer layer. According to the present invention, a dielectric layer may be spray coated onto a substrate, and the electrode and PEIE layers (and an optional metal oxide nanoparticle layer) may be respectively spray coated onto the dielectric layer. A spray coated dielectric layer may have any dry film thickness, provided the dielectric layer provides a base layer with sufficiently low surface roughness (less than 25 nanometer Ra, for example).

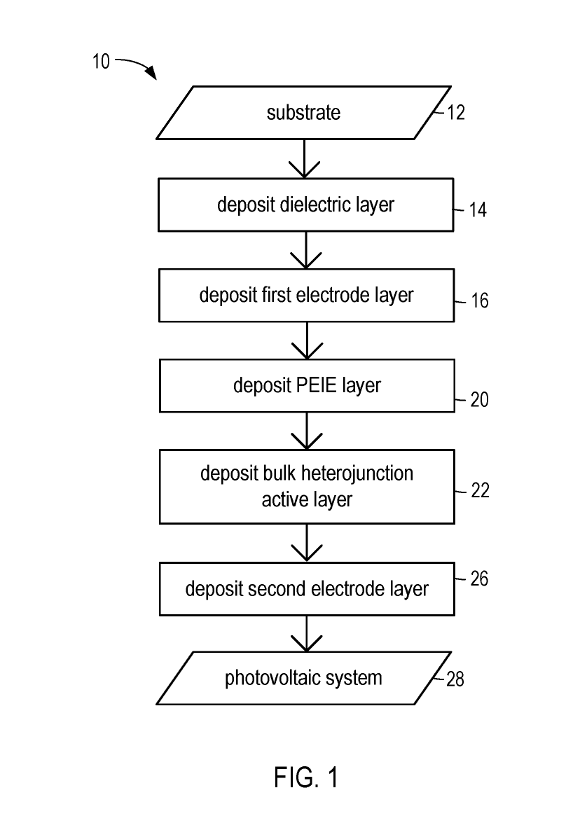

The processes for producing low work function electrodes described in this specification may be incorporated into processes for producing photovoltaic systems. FIG. 1 illustrates a process 10 for producing a photovoltaic system in accordance with the present invention. A substrate is provided at step 12. The substrate may comprise any substrate that is or can be exposed to sunlight, such as, for example, buildings, vehicles, modular panels, photovoltaic device substrates, and the like. A dielectric layer is then deposited onto the substrate at step 14. The dielectric layer may comprise a spray coated layer, as described above. For example, the dielectric layer may comprise a spray coated layer comprising a cured acrylic urethane clear-coat or a combination of an underlying epoxy primer layer and an overlying acrylic urethane clear-coat layer. A first electrode layer is subsequently deposited onto the dielectric layer at step 16. The first electrode layer may comprise a spray coated layer, as described above. For example, the first electrode layer may comprise a spray coated PEDOT:PSS PH1000 layer, a spray coated silver layer formed from the reaction products of a Tollens' reaction, or a spray coated layer of dielectric material comprising metallic particles embedded in the dielectric material. A PEIE layer is deposited onto the first electrode layer at step 20. The PEIE layer can be spray coated onto the first electrode layer, as described above.

A bulk heterojunction active layer is then deposited onto the PEIE layer at step 22 of the process illustrated in FIG. 1. The bulk heterojunction active layer may comprise an organic, semiconducting, low band gap polymer that functions as an electron donor when contacted with visible light. Typically the bulk heterojunction active layer comprises a blend comprising an organic, semiconducting, low band gap polymer and an electron acceptor compound. For example, the bulk heterojunction active layer may comprise a blend of poly(3-hexyl thiophene) and [6,6]-phenyl C₆₁-butyric acid methyl ester (P3HT:PCBM). Other low band gap polymers suitable for the bulk heterojunction active layer include, for example, poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]] (PTB7). PTB7 has the following general chemical structure:

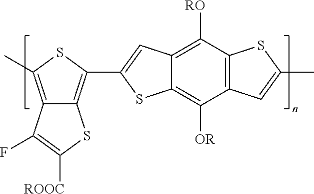

wherein R is a 2-ethylhexyl group and n denotes the repeating units of the polymer. Other suitable low band gap polymers include, but are not limited to, poly[2,6-(4,4-bis-(2-ethylhexyl)-4H-cyclopenta[2,1-b;3,4-b′]dithiophene)-alt-4,7(2,1,3-benzothiadiazole)] (PCPDTBT), which has the following general chemical structure (n denotes the repeating units of the polymer):

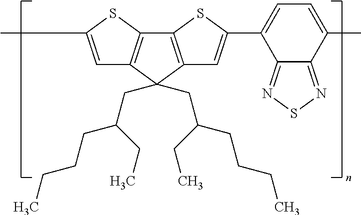

and poly[2,1,3-benzothiadiazole-4,7-diyl[4,4-bis(2-ethylhexyl)-4H-silolo[3,2-b:4,5-b′]dithiophene-2,6-diyl]] (Si-PCPDTBT), which has the following general chemical structure (n denotes the repeating units of the polymer):

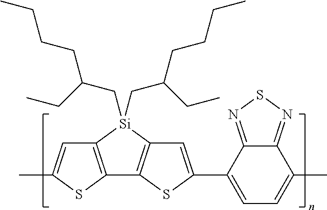

In addition to the photoactive polymers described above, it is understood that the processes and systems described in this specification can use any suitable photoactive low band gap polymers that produce electron-hole pairs when blended with an electron acceptor compound such as, for example, a fullerene compound, in a bulk heterojunction active layer exposed to light. Low band gap polymers may be used to achieve improved photovoltaic efficiency (η).

The bulk heterojunction active layer may be spray coated onto the PEIE layer. The spray coating of bulk heterojunction active layers is described, for example, in U.S. Patent Application Publication No. 2009/0155459 A1, which is incorporated by reference into this specification. The bulk heterojunction active layer may, for example, be spray coated onto the PEIE layer using solutions of low band gap electron donor polymers and electron acceptor compounds, as defined above, in chlorinated solvents or non-chlorinated solvents. For example, low band gap electron donor polymers and electron acceptor compounds can be dissolved in chlorinated solvents such as, for example, 1-chloronaphthalene, chlorobenzenes, di-chlorobenzenes, and mixtures of any thereof. Alternatively, low band gap electron donor polymers and electron acceptor compounds can be dissolved in non-chlorinated solvents such as, for example, ortho-xylene, para-xylene, ortho- and para-xylene blends, other xylene blends, tetrahydrothiophene, anisole, and mixtures of any thereof. Other co-solvents and additives that may be added to any non-chlorinated solvent used to dissolve low band gap electron donor polymers and electron acceptor compounds can include, but are not limited to, dimethylnaphthalene, terpineol, and/or 1,8-diiodooctane (DIO). A spray coated active layer may typically have a dry film thickness in the range of 180 nanometers to 240 nanometers, or any sub-range subsumed therein, such as, for example, 200-220 nanometers.

A second electrode layer is then deposited onto the active layer at step 26 of the process according to FIG. 1. The second electrode layer can be any electrode layer as defined above in the context of the first electrode layer. Thus it may, for example, comprise a spray coated electrode layer, as described above. For example, the second electrode layer may comprise a spray coated PEDOT:PSS PH1000 layer or a spray coated silver layer such as a silver layer formed from the reaction products of a Tollens' reaction. The second electrode layer may, for example, comprise a blend of PEDOT:PSS PH1000 and a second PEDOT:PSS-based polymeric material, such as, for example, a PEDOT:PSS-based polymeric material comprising poly(3,4-ethylenedioxythiophene), poly(styrene sulfonate), N-methyl-2-pyrrolidone, a gamma-glycidoxypropyltrimethoxysilane crosslinking agent, isopropanol, and an acetylenic glycol-based nonionic surfactant. This formulation is referred to in this specification, including the claims, as “PEDOT:PSS CPP.”

In some examples of the present invention, the second electrode layer may comprise a spray coated layer that is deposited from a formulation comprising anhydrous PEDOT:PSS dispersed in an anhydrous alcohol or alcohol mixture such as, for example, ethanol, 2-propanol, ethylene glycol, or mixtures of any thereof. This formulation is referred to in this specification, including the claims, as “A-PEDOT:PSS.” The second electrode layer may be formed by spray coating PEDOT:PSS PH1000, PEDOT:PSS CPP, or A-PEDOT:PSS, or a combination of any thereof, onto the active layer.

The second electrode layer should be at least partially transparent to light in order for incident light to transmit through the second electrode layer and enter into the bulk heterojunction active layer. A second electrode layer comprising a spray coated silver layer may, for example, have a dry film thickness in the range of 25 nanometers to 75 nanometers, or any sub-range subsumed therein, such as, for example, 50-60 nanometers. A second electrode layer comprising a spray coated PEDOT:PSS PH1000 layer, or a spray coated PEDOT:PSS CPP layer, or a spray coated A-PEDOT:PSS layer, or a spray coated layer comprising a blend of any two or all three of PEDOT:PSS PH1000, PEDOT:PSS CPP, and/or A-PEDOT:PSS, may, for example, have a dry film thickness in the range of 100 nanometers to 200 nanometers, or any sub-range subsumed therein, such as, for example, 160-180 nanometers.

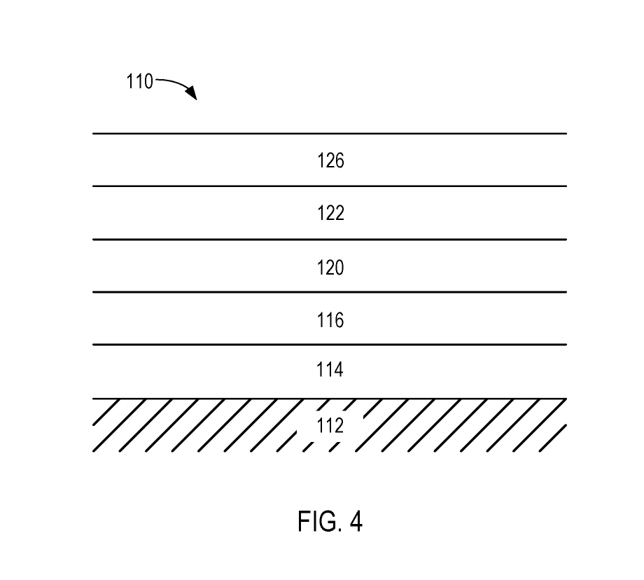

A complete photovoltaic system is provided at step 28 of the process depicted in FIG. 1 after the serial deposition of the aforementioned layers. FIG. 4 schematically illustrates a photovoltaic produced according to the process illustrated in FIG. 1. The photovoltaic system 110 comprises the following layers stacked in the following order starting from the substrate 112 at the bottom: a dielectric layer 114 over the substrate 112, a first electrode layer 116 over the dielectric layer 114, a PEIE layer 120 over the first electrode layer 116, a bulk heterojunction active layer 122 over the PEIE layer 120, and a second electrode layer 126 over the bulk heterojunction active layer 122. The constituting layers may each be as described above. The first and second electrode layers 116 and 126 may thus independently comprise, for example, a PEDOT:PSS-based layer and/or a silver layer. The second electrode layer 126 may, for example, comprise a blend of any two or more of PEDOT:PSS PH1000, PEDOT:PSS CPP, and/or A-PEDOT:PSS. The first electrode layer 116 may comprise a dielectric material comprising metallic particles embedded in the dielectric material. The bulk heterojunction active layer 122 may, for example, comprise a P3HT:PCBM layer, PTB7:PCBM layer, a PCPDTBT:PCBM layer, or a Si-PCPDTBT:PCBM layer.

In the photovoltaic system 110, the first electrode layer 116 generally has a lower work function than the second electrode layer 126, even if these two electrode layers are made of the same material (e.g., a PEDOT:PSS-based material or silver), because of the PEIE layer 120 located between and in contact with the first electrode layer 116 and the active layer 122. The first electrode layer 116 functions as a cathode and the second electrode layer 126 functions as an at least partially transparent anode. The at least partial transparency of the second electrode layer 126 is necessary for incident light to enter into the active layer 122 and produce excitons that dissociate into electrons (collected through the cathode layer 116) and holes (collected through the anode layer 126).

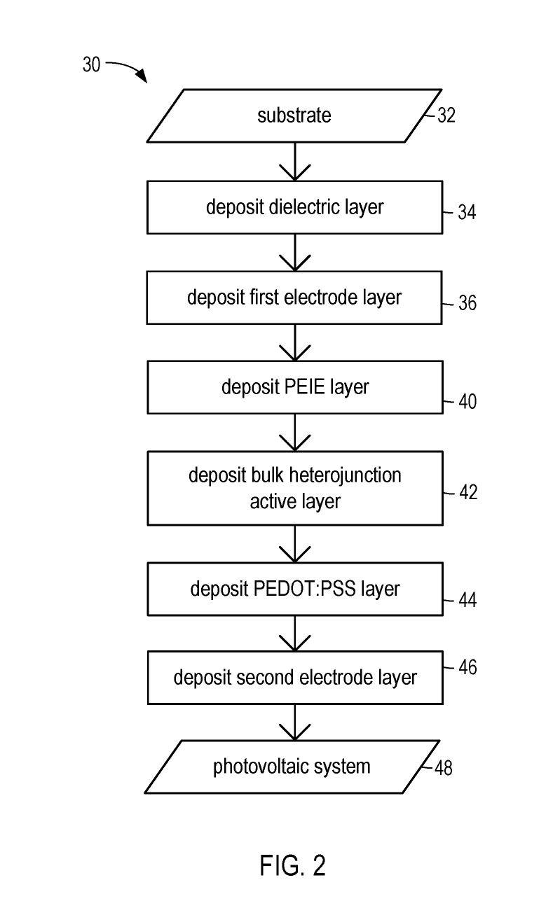

FIG. 2 illustrates another process 30 for producing a photovoltaic system according to the present invention. The process 30 illustrated in FIG. 2 is similar to the process 10 illustrated in FIG. 1, but comprises an additional step 44. A substrate is provided at step 32. The substrate may comprise any suitable substrate as defined above. A dielectric layer is then deposited onto the substrate at step 34. The dielectric layer may, for example, comprise a spray coated layer, as described above. For example, the dielectric layer may comprise a spray coated layer comprising a cured acrylic urethane clear-coat or a combination of an underlying epoxy primer layer and an overlying acrylic urethane clear-coat layer. A first electrode layer is subsequently deposited onto the dielectric layer at 36. The first electrode layer may, for example, comprise a spray coated layer, as described above. For example, the first electrode layer may comprise a spray coated PEDOT:PSS PH1000 layer, a spray coated silver layer formed from the reaction products of a Tollens' reaction, or a spray coated layer of dielectric material comprising metallic particles embedded in the dielectric material. A PEIE layer is deposited onto the first electrode layer at step 40. The PEIE layer is spray coated onto the first electrode layer, as described above.

A bulk heterojunction active layer is then deposited onto the PEIE layer at step 42. The bulk heterojunction active layer may comprise a blend comprising an organic semiconducting polymer (functioning as an electron donor) and an electron acceptor compound. For example, the bulk heterojunction active layer may comprise a blend of poly(3-hexyl thiophene) and [6,6]-phenyl C₆₁-butyric acid methyl ester (P3HT:PCBM), or the bulk heterojunction active layer may comprise a PTB7:PCBM blend, a PCPDTBT:PCBM blend, or a Si-PCPDTBT:PCBM blend. The bulk heterojunction active layer may be spray coated onto the PEIE layer as described above in connection with FIG. 1. The spray coating of organic photovoltaic active layers is described, for example, in U.S. Patent Application Publication No. 2009/0155459 A1, which is incorporated by reference into this specification.

A PEDOT:PSS-based polymeric layer is deposited onto the active layer at step 44. This layer may comprise a hole transport layer. In some aspects, the PEDOT:PSS-based polymeric layer may be spray coated onto the active layer at 44 using a formulation comprising poly(3,4-ethylenedioxythiophene), poly(styrene sulfonate), N-methyl-2-pyrrolidone, a gamma-glycidoxypropyltrimethoxysilane crosslinking agent, isopropanol, and an acetylenic glycol-based nonionic surfactant. As described above, this formulation is referred to in this specification, including the claims, as “PEDOT:PSS CPP.” The PEDOT:PSS-based polymeric layer may be spray coated onto the active layer at 44 using a formulation comprising any one, two, or all three of PEDOT:PSS PH1000, PEDOT:PSS CPP, and/or A-PEDOT:PSS.

Bulk heterojunction active layers comprising P3HT:PCBM or PTB7:PCBM, for example, may exhibit poor aqueous wetting properties that may result in insufficient adhesion and electrical conductance between the active layers and overlying electrode layers deposited from aqueous solutions (e.g., spray coated PEDOT:PSS PH1000 formulations and silver layers produced using sprayed Tollens' reagents). PEDOT:PSS CPP formulations comprising poly(3,4-ethylenedioxythiophene), poly(styrene sulfonate), N-methyl-2-pyrrolidone, a gamma-glycidoxypropyltrimethoxysilane crosslinking agent, isopropanol, and an acetylenic glycol-based nonionic surfactant, as well as A-PEDOT:PSS, exhibit better wetting on bulk heterojunction active layers, particularly P3HT:PCBM-based, PTB7:PCBM-based, PCPDTBT:PCBM-based, or a Si-PCPDTBT:PCBM-based active layers. Layers deposited from formulations comprising PEDOT:PSS CPP and/or A-PEDOT:PSS also have a different morphology than films formed from other PEDOT:PSS formulations, such as PEDOT:PSS PH1000, resulting in improved electrical conductance between underlying active layers and overlying electrode layers. The PEDOT:PSS CPP and/or A-PEDOT:PSS layer spray coated or otherwise deposited at step 44 may, for example, have a dry film thickness in the range of 75 nanometers to 125 nanometers, or any sub-range subsumed therein, such as, for example, 90-100 nanometers. A second electrode layer is deposited onto the PEDOT:PSS CPP and/or A-PEDOT:PSS layer at step 46. The second electrode layer may comprise a spray coated layer, as described above. For example, the second electrode layer may comprise a spray coated PEDOT:PSS PH1000 layer or a spray coated silver layer formed from the reaction products of a Tollens' reaction. Alternatively, the second electrode layer may comprise a blend of any two or all three of PEDOT:PSS PH1000, PEDOT:PSS CPP, and/or A-PEDOT:PSS.

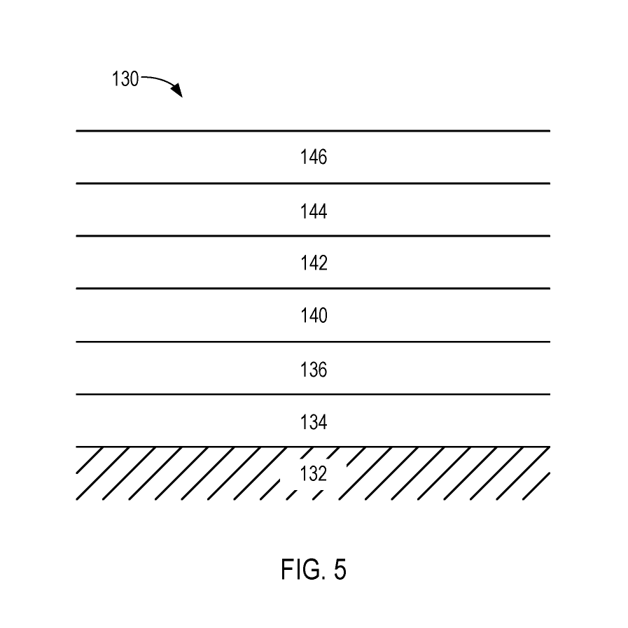

A complete photovoltaic system is provided at step 48 of the process depicted in FIG. 2 after the serial deposition of the layers. FIG. 5 schematically illustrates a photovoltaic system 130 produced according to the process illustrated in FIG. 2. The photovoltaic system 130 comprises the following layers stacked in the following order starting from the substrate 132 at the bottom: a dielectric layer 134 over the substrate 132, a first electrode layer 136 over the dielectric layer 134, a PEIE layer 140 over the first electrode layer 136, a bulk heterojunction active layer 142 over the PEIE layer 140, a PEDOT:PSS CPP and/or A-PEDOT:PSS hole transport layer 144 over the bulk heterojunction active layer 142, and a second electrode layer 146 over the hole transport layer 144. The constituting layers may each be as described above. The first and second electrode layers 136 and 146 may thus independently comprise, for example, a PEDOT:PSS-based layer and/or a silver layer. The second electrode layer 146 may comprise a blend of any two or all three of PEDOT:PSS PH1000, PEDOT:PSS CPP, and/or A-PEDOT:PSS. The first electrode layer 136 may comprise a dielectric material comprising metallic particles embedded in the dielectric material. The bulk heterojunction active layer 142 may, for example, comprise a P3HT:PCBM layer, a PTB7:PCBM layer, a PCPDTBT:PCBM layer, or a Si-PCPDTBT:PCBM layer.

In the photovoltaic system 130, the first electrode layer 136 generally has a lower work function than the second electrode layer 146, even if these two electrode layers are made of the same material (e.g., a PEDOT:PSS-based material or silver), because of the PEIE layer 140 located between and in contact with the first electrode layer 136 and the active layer 142. The first electrode layer 136 functions as a cathode and the second electrode layer 146 functions as an at least partially transparent anode. The PEDOT:PSS CPP and/or A-PEDOT:PSS hole transport layer 144 functions as an at least partially transparent hole transport layer. The at least partial transparency of the second electrode layer 146 and the PEDOT:PSS CPP and/or A-PEDOT:PSS hole transport layer 144 is necessary for incident light to enter into the active layer 142 and produce excitons that dissociate into electrons (collected through the cathode layer 136) and holes (collected through the hole transport layer 144 and the anode layer 146).

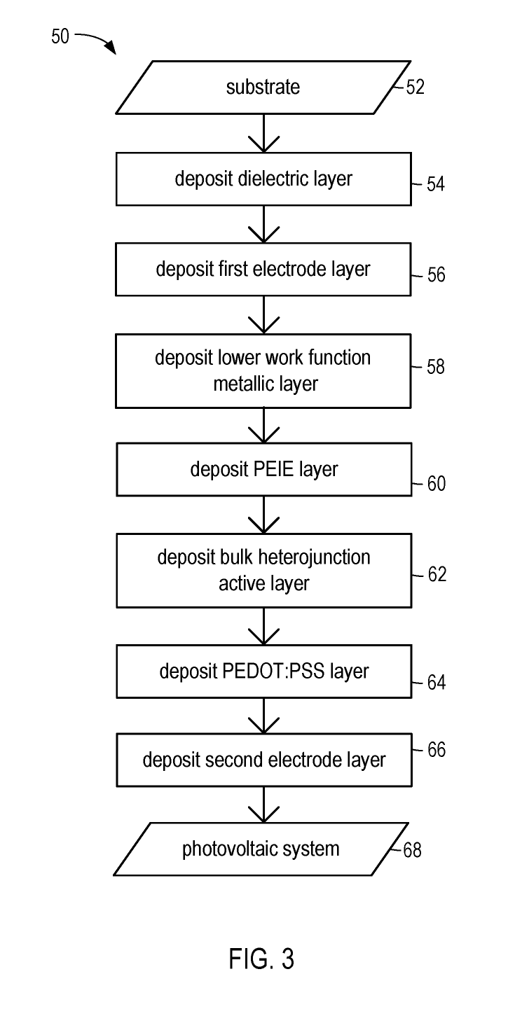

FIG. 3 illustrates another process 50 for producing a photovoltaic system according to the present invention. The process 50 illustrated in FIG. 3 is similar to the process 30 illustrated in FIG. 2, but comprises an additional step 58. A substrate is provided at step 52. The substrate may comprise any substrate that is or can be exposed to sunlight, such as, for example, buildings, vehicles, modular panels, photovoltaic device substrates, and the like, as described above. A dielectric layer is then deposited onto the substrate at step 54. The dielectric layer may, for example, comprise a spray coated layer, as described above. For example, the dielectric layer may comprise a spray coated layer comprising a cured acrylic urethane clear-coat or a combination of an underlying epoxy primer layer and an overlying acrylic urethane clear-coat layer. A first electrode layer is subsequently deposited onto the dielectric layer at step 56. The first electrode layer may, for example, comprise a spray coated layer, as described above. For example, the first electrode layer may comprise a spray coated PEDOT:PSS PH1000 layer, a spray coated silver layer such as a silver layer formed from the reaction products of a Tollens' reaction, or a spray coated layer of dielectric material comprising metallic particles embedded in the dielectric material.

A lower work function metallic layer is then deposited onto the first electrode layer at step 58. The lower work function metallic layer may comprise a metal such as, for example, titanium or chromium. A lower work function metallic layer (such as a titanium layer or a chromium layer) may be deposited onto the first electrode by vacuum thermal evaporation-deposition or cold spraying, for example. The lower work function metallic layer deposited at 58 may, for example, have a dry film thickness in the range of 5 nanometers to 25 nanometers, or any sub-range subsumed therein, such as, for example, 10-20 nanometers.

A PEIE layer is then deposited onto the lower work function metallic layer at step 60. The PEIE layer may be spray coated onto the lower work function metallic layer in the same manner described above in which a PEIE layer is spray coated onto an electrode layer. A bulk heterojunction active layer is then deposited onto the PEIE layer at step 62. The bulk heterojunction active layer may, for example, comprise a blend comprising an organic semiconducting polymer (functioning as an electron donor) and an electron acceptor compound. For example, the bulk heterojunction active layer may comprise a blend of poly(3-hexyl thiophene) and [6,6]-phenyl C₆₁-butyric acid methyl ester (P3HT:PCBM), or the bulk heterojunction active layer may comprise a PTB7:PCBM blend, a PCPDTBT:PCBM blend, or a Si-PCPDTBT:PCBM blend. The bulk heterojunction active layer may be spray coated onto the PEIE layer as described above in connection with FIGS. 1 and 2. The spray coating of organic photovoltaic active layers is described, for example, in U.S. Patent Application Publication No. 2009/0155459 A1, which is incorporated by reference into this specification.

A PEDOT:PSS-based hole transport layer is then deposited onto the active layer at step 64. The PEDOT:PSS-based hole transport layer may, for example, be spray coated onto the active layer using a formulation comprising poly(3,4-ethylenedioxythiophene), poly(styrene sulfonate), N-methyl-2-pyrrolidone, a gamma-glycidoxypropyltrimethoxysilane crosslinking agent, isopropanol, and an acetylenic glycol-based nonionic surfactant, or using a formulation comprising A-PEDOT:PSS, as described above in connection with FIG. 2. A second electrode layer is then deposited onto the PEDOT:PSS-based hole transport layer at step 66. The second electrode layer may, for example, comprise a spray coated layer, as described above. For example, the second electrode layer may comprise a spray coated PEDOT:PSS PH1000 layer or a spray coated silver layer such as a silver layer formed from the reaction products of a Tollens' reaction. According to the present invention the second electrode layer may also comprise a blend comprising any one, two, or all three of PEDOT:PSS PH1000, PEDOT:PSS CPP, and/or A-PEDOT:PSS.

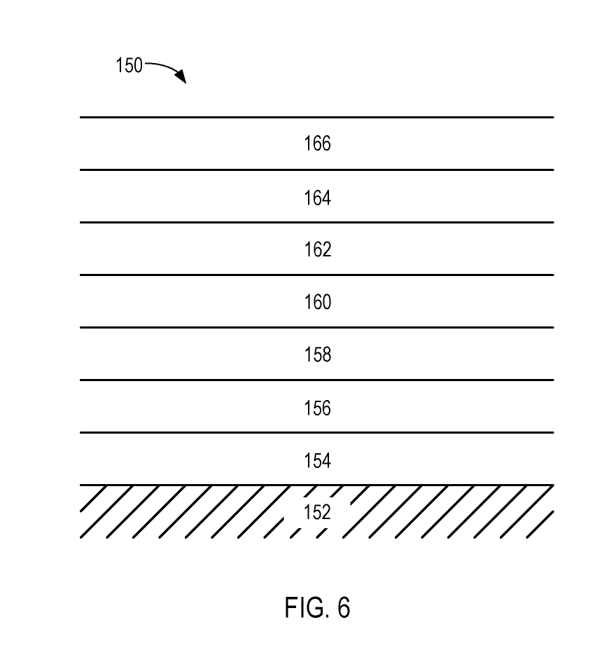

A complete photovoltaic system is provided at step 68 of the process depicted in FIG. 3 after the serial deposition of the aforementioned layers in steps 54-66. FIG. 6 schematically illustrates a photovoltaic system 150 produced according to the process illustrated in FIG. 3. The photovoltaic system 150 comprises the following layers stacked in the following order starting from the substrate 152 at the bottom: a dielectric layer 154 over the substrate 152, a first electrode layer 156 over the dielectric layer 154, a lower work function metallic layer 158 over the first electrode layer 156, a PEIE layer 160 over the lower work function metallic layer 158, a bulk heterojunction active layer 162 over the PEIE layer 160, a PEDOT:PSS-based hole transport layer 164 over the bulk heterojunction active layer 162, and a second electrode layer 166 over the PEDOT:PSS-based hole transport layer 164. The constituting layers may each be as described above. The first and second electrode layers 156 and 166 may thus independently comprise, for example, a PEDOT:PSS-based layer and/or a silver layer. The second electrode layer 166 may comprise a blend comprising any one, two, or all three of PEDOT:PSS PH1000, PEDOT:PSS CPP, and/or A-PEDOT:PSS. The first electrode layer 156 may comprise a dielectric material comprising metallic particles embedded in the dielectric material. The bulk heterojunction active layer 162 may comprise a P3HT:PCBM layer, a PTB7:PCBM layer, a PCPDTBT:PCBM layer, or a Si-PCPDTBT:PCBM layer.

In the photovoltaic system 150, the lower work function metallic layer 158 and the PEIE layer 160 function together as electron transport layers that conduct photo-excited and dissociated electrons from the active layer 162 to the first electrode layer 156. By functioning as electron transport layers, the lower work function metallic layer 158 and the PEIE layer 160 effectively lower the work function of the first electrode layer 156, even if the first electrode layer 156 and the second electrode layer 166 are made of the same material (e.g., a PEDOT:PSS-based material or silver). The first electrode layer 156 functions as a cathode and the second electrode layer 166 functions as an at least partially transparent anode. The PEDOT:PSS-based hole transport layer 164 functions as an at least partially transparent hole transport layer. The at least partial transparency of the second electrode layer 166 and the PEDOT:PSS-based hole transport layer 164 is necessary for incident light to enter into the active layer 162 and produce excitons that dissociate into electrons (collected through the electron transport layers 160 and 158 and the cathode layer 156) and holes (collected through the hole transport layer 164 and the anode layer 166).

Although not illustrated in FIGS. 1-6, it is understood that according to the present invention, optionally an inorganic hole transport layer may be spray coated or otherwise deposited onto the bulk heterojunction active layer before spray coating or otherwise depositing a PEDOT:PSS-based hole transport layer, if present, and the second electrode layer. For example, a carbon nanotube layer, a graphene layer, a metal oxide layer may be spray coated or otherwise deposited onto the bulk heterojunction active layer to form an inorganic hole transport layer before spray coating or otherwise depositing a PEDOT:PSS-based hole transport layer, if present, and the second electrode layer (e.g., a silver layer or a layer comprising a combination of any one, two, or all three of PEDOT:PSS PH1000, PEDOT:PSS CPP, and/or A-PEDOT:PSS). In some examples, a metal oxide hole transport layer may be spray coated or otherwise deposited onto the bulk heterojunction active layer before spray coating or otherwise depositing a second electrode layer. A metal oxide hole transport layer may comprise, for example, a molybdenum trioxide layer or a vanadium oxide (V₂O₅) layer. The spray coating of molybdenum trioxide layers, for example, is described in Suzuki et al., “Electrosprayed molybdenum trioxide aqueous solution and its application in organic photovoltaic cells,” PLOS One, vol. 9, no. 8, August 2014, which is incorporated by reference into this specification. A vanadium oxide layer may be spray coated, for example, using aqueous solutions of vanadium oxytriisopropoxide and atomic layer deposition (ALD) techniques. The ALD of vanadium oxide layers using aqueous solutions of vanadium oxytriisopropoxide is described, for example, in Musschoot et al., “ALD of Vanadium Oxide,” ESC Transactions, 25 (4), 2009, and Banerjee et al., “Mixed mode, ionic-electronic diode using atomic layer deposition of V₂O₅ and ZnO films,” Journal of Materials Chemistry, 21, 2011, which are incorporated by reference into this specification.

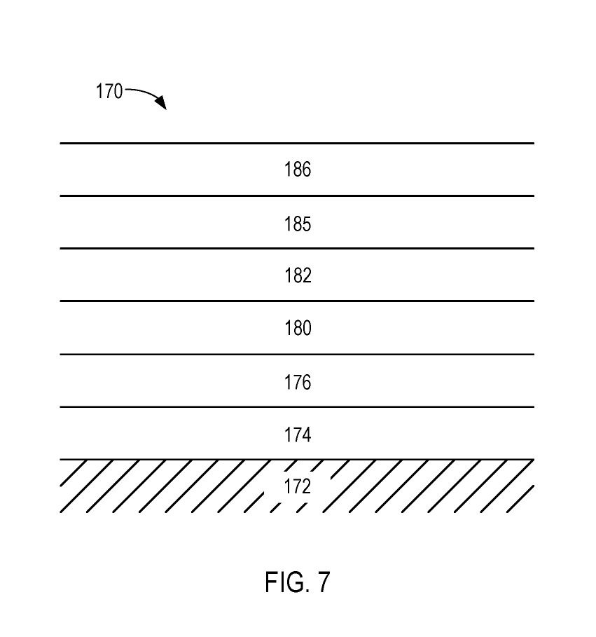

FIG. 7 schematically illustrates another photovoltaic system 170 produced according to the present invention. The photovoltaic system 170 comprises the following layers stacked in the following order starting from the substrate 172 at the bottom: a dielectric layer 174 over the substrate 172, a first electrode layer 176 over the dielectric layer 174, a PEIE layer 180 over the first electrode layer 176, a bulk heterojunction active layer 182 over the PEIE layer 180, an inorganic hole transport layer 185 over the bulk heterojunction active layer 182, and a second electrode layer 186 over the inorganic hole transport layer 184. The constituting layers may each be as described above. The first and second electrode layers 176 and 186 may thus independently comprise, for example, a PEDOT:PSS-based layer and/or a silver layer. The second electrode layer 186 may alternatively comprise a blend comprising any one, two, or all three of PEDOT:PSS PH1000, PEDOT:PSS CPP, and/or A-PEDOT:PSS. The first electrode layer 176 may comprise a dielectric material comprising metallic particles embedded in the dielectric material. The bulk heterojunction active layer 182 may, for example, comprise a P3HT:PCBM layer, a PTB7:PCBM layer, a PCPDTBT:PCBM layer, or a Si-PCPDTBT:PCBM layer. The inorganic hole transport layer 185 may comprise a molybdenum trioxide layer, a graphene layer, or a carbon nanotube layer, for example.

In the photovoltaic system 170, the first electrode layer 176 has a lower work function than the second electrode layer 186, even if these two electrode layers are made of the same material (e.g., a PEDOT:PSS-based material or silver), because of the PEIE layer 180 located between and in contact with the first electrode layer 176 and the bulk heterojunction active layer 182. The first electrode layer 176 functions as a cathode and the second electrode layer 186 functions as an at least partially transparent anode. The inorganic hole transport layer 185 functions as an at least partially transparent hole transport layer. The at least partial transparency of the second electrode layer 186 and the inorganic hole transport layer 185 is necessary for incident light to enter into the active layer 182 and produce excitons that dissociate into electrons (collected through the cathode layer 176) and holes (collected through the hole transport layer 185 and the anode layer 186).

It is understood that the layers shown in FIG. 7 can all be deposited by spray coating operations in a process for producing the photovoltaic system 170. In addition, although not illustrated in FIG. 7, it is understood that according to the present invention, an optional organic hole transport layer (such as the PEDOT:PSS CPP and/or A-PEDOT:PSS hole transport layer described in connection with FIGS. 2 and 5) can be deposited between the inorganic hole transport layer 185 and the second electrode layer 186. In addition, although not illustrated in FIG. 7, it is understood that, an optional lower work function metallic layers (such as a chromium or titanium layer as described in connection with FIGS. 3 and 6) can be deposited between the first electrode layer 176 and the PEIE layer 180.

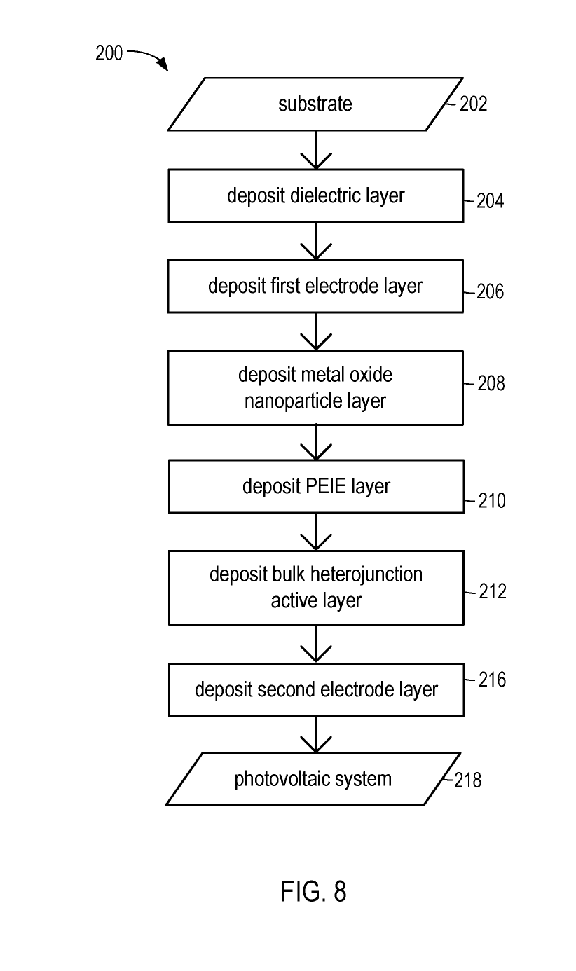

FIG. 8 illustrates another process 200 for producing a photovoltaic system according to the present invention. The process 200 illustrated in FIG. 3 is similar to the process 10 illustrated in FIG. 1, but comprises an additional step 208. A substrate is provided at step 202. The substrate may comprise any substrate that is or can be exposed to sunlight, such as, for example, buildings, vehicles, modular panels, photovoltaic device substrates, and the like, as described above. A dielectric layer is then deposited onto the substrate at step 204. The dielectric layer may, for example, comprise a spray coated layer, as described above. For example, the dielectric layer may comprise a spray coated layer comprising a cured acrylic urethane clear-coat or a combination of an underlying epoxy primer layer and an overlying acrylic urethane clear-coat layer. A first electrode layer is subsequently deposited onto the dielectric layer at step 206. The first electrode layer may, for example, comprise a spray coated layer, as described above. For example, the first electrode layer may comprise a spray coated PEDOT:PSS-based layer, a spray coated silver layer such as a silver layer formed from the reaction products of a Tollens' reaction, or a spray coated layer of dielectric material comprising metallic particles embedded in the dielectric material.

A metal oxide nanoparticle layer is then deposited onto the first electrode layer at step 208. The metal oxide nanoparticle layer may comprise the metal oxide nanoparticles described above, such as, for example, zinc oxide nanoparticles. The metal oxide nanoparticle layer deposited at 208 may, for example, have a dry film thickness in the range of 10-125 nanometers, or any subrange subsumed therein, such as, for example, 10-50 nanometers, 10-25 nanometers, 10-15 nanometers, or 12-15 nanometers. The metal oxide nanoparticle layer may be spray coated onto the first electrode layer at step 208.

A PEIE layer is then deposited onto the metal oxide nanoparticle layer at step 210. The PEIE layer may be spray coated onto the metal oxide nanoparticle layer in the same manner described above in which a PEIE layer is spray coated onto an electrode layer. A bulk heterojunction active layer is then deposited onto the PEIE layer at step 212. The bulk heterojunction active layer may, for example, comprise a blend comprising an organic semiconducting polymer (functioning as an electron donor) and an electron acceptor compound. For example, the bulk heterojunction active layer may comprise a blend of poly(3-hexyl thiophene) and [6,6]-phenyl C₆₁-butyric acid methyl ester (P3HT:PCBM), or the bulk heterojunction active layer may comprise a PTB7:PCBM blend, a PCPDTBT:PCBM blend, or a Si-PCPDTBT:PCBM blend. The bulk heterojunction active layer may be spray coated onto the PEIE layer as described above in connection with FIGS. 1, 2, and 3. The spray coating of organic photovoltaic active layers is described, for example, in U.S. Patent Application Publication No. 2009/0155459 A1, which is incorporated by reference into this specification.

A second electrode layer is then deposited onto the bulk heterojunction active layer at step 216. The second electrode layer may, for example, comprise a spray coated layer, as described above. For example, the second electrode layer may comprise a spray coated PEDOT:PSS-based layer or a spray coated silver layer such as a silver layer formed from the reaction products of a Tollens' reaction. According to the present invention the second electrode layer may also comprise a blend comprising any one, two, or all three of PEDOT:PSS PH1000, PEDOT:PSS CPP, and/or A-PEDOT:PSS, such as, for example, a blend of PEDOT:PSS CPP and A-PEDOT:PSS.

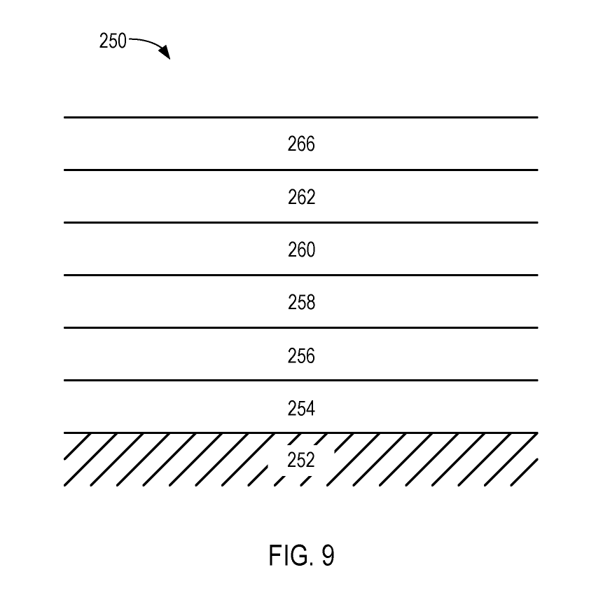

A complete photovoltaic system is provided at step 218 of the process depicted in FIG. 8 after the serial deposition of the aforementioned layers in steps 204-216. FIG. 9 schematically illustrates a photovoltaic system 250 produced according to the process illustrated in FIG. 8. The photovoltaic system 250 comprises the following layers stacked in the following order starting from the substrate 252 at the bottom: a dielectric layer 254 over the substrate 252, a first electrode layer 256 over the dielectric layer 254, a metal oxide nanoparticle layer 258 over the first electrode layer 256, a PEIE layer 260 over the metal oxide nanoparticle layer 258, a bulk heterojunction active layer 262 over the PEIE layer 260, and a second electrode layer 266 over the bulk heterojunction active layer 262. The constituting layers may each be as described above. The first and second electrode layers 256 and 266 may thus independently comprise, for example, a PEDOT:PSS-based layer and/or a silver layer. The second electrode layer 266 may comprise a blend comprising any one, two, or all three of PEDOT:PSS PH1000, PEDOT:PSS CPP, and/or A-PEDOT:PSS. The first electrode layer 256 may comprise a dielectric material comprising metallic particles embedded in the dielectric material. The bulk heterojunction active layer 262 may comprise a P3HT:PCBM layer, a PTB7:PCBM layer, a PCPDTBT:PCBM layer, or a Si-PCPDTBT:PCBM layer.

In the photovoltaic system 250, the metal oxide nanoparticle layer 258 and the PEIE layer 260 function together as electron transport layers that conduct photo-excited and dissociated electrons from the active layer 262 to the first electrode layer 256. By functioning as electron transport layers, the metal oxide nanoparticle layer 258 and the PEIE layer 260 effectively lower the work function of the first electrode layer 256, even if the first electrode layer 256 and the second electrode layer 266 are made of the same material (e.g., a PEDOT:PSS-based material or silver). The first electrode layer 256 functions as a cathode and the second electrode layer 266 functions as an at least partially transparent anode. The at least partial transparency of the second electrode layer 266 is necessary for incident light to enter into the active layer 262 and produce excitons that dissociate into electrons (collected through the electron transport layers 260 and 258 and the cathode layer 256) and holes (collected through the anode layer 266).

Although not illustrated in FIGS. 1-9, it is understood that according to the present invention, the second electrode layers (e.g., second electrode layers 126, 146, 166, 186, and 266) can comprise a hybrid bi-layer structure comprising an organic layer and an inorganic layer. The hybrid bi-layer structure can, for example, comprise an organic layer comprising any one, two, or all three of PEDOT:PSS PH1000, PEDOT:PSS CPP, and/or A-PEDOT:PSS, and an inorganic layer comprising an at least partially transparent silver layer. The organic layer (e.g., PEDOT:PSS CPP and/or A-PEDOT:PSS) of the hybrid second electrode bi-layer may be in direct physical contact with an underlying bulk heterojunction active material layer, or in direct physical contact with an optional underlying hole transport layer. The inorganic layer (e.g., silver) of the hybrid second electrode bi-layer may be in direct physical contact with the organic layer of the hybrid second electrode bi-layer. The entire hybrid second electrode bi-layer is at least partially transparent so that incident light can enter into the active layer and produce excitons that dissociate into electrons and holes.

Although not illustrated in FIGS. 1-9, it is understood that in implementations where the second electrode layers (e.g., second electrode layers 126, 146, 166, 186, and 266) or the organic layer of a hybrid second electrode bi-layer implementation comprise any one, two, or all three of PEDOT:PSS PH1000, PEDOT:PSS CPP, and/or A-PEDOT:PSS, the layers may further comprise metallic nanoparticles embedded in the layers. For example, second electrode layers may comprise gold nanoparticles, copper nanoparticles, platinum nanoparticles, and/or silver nanoparticles embedded in PEDOT:PSS-based layers. According to the present invention, the nanoparticles can, for example, have an average particle size of less than 1000 nanometers, such as 5-500 nanometers or 10-100 nanometers.

Although not illustrated in FIGS. 1-9, it is understood that according to the present invention, an optional outer protective barrier layer may be deposited onto the second electrode, provided that any outer protective barrier layer is at least partially transparent. Like the base dielectric layer, described above, an outer protective barrier layer may be electrically, chemically, and mechanically inert to the underlying functional photovoltaic layers. An outer protective barrier layer may hermetically seal the underlying functional photovoltaic layers and provide barrier protection against moisture or other potentially harmful environmental agents. An outer protective barrier layer may possess certain properties, such as, for example, a water vapor transmission rate of less than 10⁻² g/m²/day or less than 10⁻⁴ g/m²/day or less than 10⁻⁶ g/m²/day. The outer protective barrier layer may moreover possess an oxygen transmission rate of less than 10⁻³ cm³/m²/day.

The processes described herein for producing low work function electrodes and for producing photovoltaic systems may be used to produce a fully-sprayed photovoltaic system, wherein each layer comprising the photovoltaic system is deposited using a spray coating operation. For example, in the processes illustrated in FIGS. 1-3 and 8, and other implementations in accordance with the present invention, each deposition step may be a spray coating step, and each layer illustrated in FIGS. 4-7 and 9 may be a spray coated layer. Additionally, although FIGS. 4-7 and 9 illustrate each layer as a continuous layer fully covering the immediately underlying layer, it is understood that the present invention also relates to implementations, wherein any overlying layer may not fully cover the immediately underlying layer. For example, the second electrode layers 126, 146, 166, 186, and 266 in FIGS. 4-7 and 9 may be spray coated or otherwise deposited in a predetermined pattern that provides for improved light transparency to the underlying active material layers.

The processes illustrated in FIGS. 1-3 and 8 only show deposition (e.g., spray coating) steps. However, additional steps may be performed between any two successive deposition/spray coating steps. For example, after the deposition or spray coating of a layer comprising a dielectric material, the layer may be subjected to curing conditions for a period of time to cure the dielectric material before the subsequent deposition or spray coating of an overlying layer. After the spray coating of a P3HT:PCBM or PTB7:PCBM active layer, for example, the deposited layer may be thermally annealed before the subsequent deposition of an inorganic hole transport layer, a PEDOT:PSS-based layer, and/or a second electrode layer. For example, a spray coated P3HT:PCBM or PTB7:PCBM active layer may be thermally annealed for about 20 minutes at about 120° C. while maintaining a substrate temperature of about 40° C. As another example, after the spray coating of a PEDOT:PSS-based hole transport layer, the deposited layer may be thermally annealed for 20 minutes at about 120° C. while maintaining a substrate temperature of about 75° C. As another example, after the spray coating of a PEDOT:PSS PH1000 layer, the deposited layer may be thermally annealed for 1 minute at about 150° C. while maintaining a substrate temperature of about 100° C. As another example, after spray coating of a metal oxide nanoparticle layer, the deposited layer may be annealed at temperatures ranging from 75° C. to 150° C., or any subrange subsumed therein, such as, for example, 100-120° C.

A preferred process according to the present invention for producing a fully-sprayed photovoltaic system comprises spray coating a first electrode layer onto a substrate, spray coating a metal oxide nanoparticle layer onto the first electrode layer, spray coating a PEIE layer onto the metal oxide nanoparticle layer, spray coating a bulk heterojunction active layer onto the PEIE layer, and spray coating a second electrode layer onto the bulk heterojunction active layer. The process may optionally further comprise spray coating a dielectric layer onto the substrate, and spray coating the first electrode layer onto the dielectric layer. The process may optionally further comprise spray coating a PEDOT:PSS-based hole transport layer onto the bulk heterojunction active layer, and spray coating the second electrode layer onto the PEDOT:PSS-based hole transport layer. The process may optionally further comprise spray coating an inorganic hole transport layer onto the bulk heterojunction active layer, and spray coating the second electrode layer onto the inorganic hole transport layer. The process may optionally further comprise spray coating a lower work function metallic layer onto the first electrode layer, and spray coating the metal oxide nanoparticle layer and/or the PEIE layer onto the metallic layer. The process may also further comprise spray coating an outer protective barrier layer onto the second electrode layer.

Another preferred process according to the present invention for producing a fully-sprayed photovoltaic system comprises spray coating a dielectric layer onto a substrate, spray coating a first silver layer onto the dielectric layer, spray coating metal oxide nanoparticle and/or a PEIE layers onto the first silver layer, spray coating a P3HT:PCBM layer or a PTB7:PCBM layer onto the PEIE layer, spray coating a PEDOT:PSS-based hole transport layer onto the P3HT:PCBM layer or PTB7:PCBM layer, and spray coating a second silver layer onto the PEDOT:PSS-based hole transport layer. The process may further comprise spray coating a titanium layer or a chromium layer onto the first silver layer, and spray coating the metal oxide nanoparticle layer and/or the PEIE layer onto the titanium or chromium layer. The process may optionally further comprise spray coating an outer protective barrier layer onto the second silver layer. This example process produces a fully-sprayed photovoltaic system comprising an at least partially transparent silver anode, a PEDOT:PSS-based hole transport layer, a P3HT:PCBM or PTB7:PCBM bulk heterojunction active layer, and a cathode layer comprising silver and having a lower work function than the silver anode resulting from the metal oxide nanoparticle and/or PEIE layers located between and contacting the P3HT:PCBM or PTB7:PCBM bulk heterojunction active layer and the cathode layer comprising silver (or the optional titanium or chromium electron transport layer).

Another preferred process according to the present invention for producing a fully-sprayed photovoltaic system comprises spray coating a dielectric layer onto a substrate, spray coating a first PEDOT:PSS PH1000 layer onto the dielectric layer, spray coating metal oxide nanoparticle and/or PEIE layers onto the first PEDOT:PSS PH1000 layer, spray coating a P3HT:PCBM layer or a PTB7:PCBM layer onto the PEIE layer, spray coating a PEDOT:PSS-based hole transport layer onto the P3HT:PCBM layer or PTB7:PCBM layer, and spray coating a second PEDOT:PSS PH1000 layer onto the PEDOT:PSS-based hole transport layer. In such process, the PEDOT:PSS-based hole transport layer is spray coated using a formulation that is different than the formulation used to spray coat the first and third PEDOT:PSS PH1000 layers, wherein the formulation used to spray coat the PEDOT:PSS-based hole transport layer exhibits better wettability on P3HT:PCBM or PTB7:PCBM layers than the formulation used to spray coat the first and second PEDOT:PSS PH1000 layers. The process may further comprise spray coating an optional titanium layer or a chromium layer onto the first PEDOT:PSS PH1000 layer, and spray coating the metal oxide and/or PEIE layers onto the titanium or chromium layer. The process may also further comprise spray coating an outer protective barrier layer onto the second PEDOT:PSS PH1000 layer. This example process produces a fully-sprayed photovoltaic system comprising an at least partially transparent PEDOT:PSS PH1000 anode, a morphologically different PEDOT:PSS-based hole transport layer, a P3HT:PCBM or PTB7:PCBM bulk heterojunction active layer, and a PEDOT:PSS PH1000 cathode having a lower work function than the PEDOT:PSS PH1000 anode resulting from the metal oxide nanoparticle and/or PEIE layers located between and contacting the P3HT:PCBM or PTB7:PCBM bulk heterojunction active layer and the PEDOT:PSS PH1000 cathode (or the optional titanium or chromium electron transport layer).

A further preferred process according to the present invention for producing a fully-sprayed photovoltaic system comprises spray coating a dielectric layer onto a substrate, spray coating a silver layer onto the dielectric layer, spray coating metal oxide nanoparticle and/or PEIE layers onto the silver layer, spray coating a P3HT:PCBM layer or a PTB7:PCBM layer onto the PEIE layer, spray coating a PEDOT:PSS-based hole transport layer onto the P3HT:PCBM or PTB7:PCBM layer, and spray coating a PEDOT:PSS PH1000 layer onto the PEDOT:PSS-based hole transport layer. In such process, the PEDOT:PSS-based hole transport layer is spray coated using a formulation that is different than the formulation used to spray coat the PEDOT:PSS PH1000 layer, wherein the formulation used to spray coat the first PEDOT:PSS-based hole transport layer exhibits better wettability on P3HT:PCBM or PTB7:PCBM layers than the formulation used to spray coat the PEDOT:PSS PH1000 layer. The process may further comprise spray coating an optional titanium layer or a chromium layer onto the silver layer, and spray coating the PEIE layer onto the titanium or chromium layer. The process may also further comprise spray coating an outer protective barrier layer onto the PEDOT:PSS PH1000 layer. This example process produces a fully-sprayed photovoltaic system comprising an at least partially transparent PEDOT:PSS PH1000 anode, a morphologically different PEDOT:PSS-based hole transport layer, a P3HT:PCBM or PTB7:PCBM bulk heterojunction active layer, and a silver cathode having a lower work function than the PEDOT:PSS PH1000 anode resulting in part from the metal oxide nanoparticle and/or PEIE layer located between and contacting the P3HT:PCBM or PTB7:PCBM layer bulk heterojunction active layer and the silver cathode (or the optional titanium or chromium electron transport layer).

Another preferred process according to the present invention for producing a fully-sprayed photovoltaic system comprises spray coating a dielectric layer onto a substrate, spray coating a PEDOT:PSS PH1000 layer onto the dielectric layer, spray coating metal oxide nanoparticle and/or PEIE layers onto the PEDOT:PSS PH1000 layer, spray coating a P3HT:PCBM layer or a PTB7:PCBM layer onto the PEIE layer, spray coating a PEDOT:PSS-based hole transport layer onto the P3HT:PCBM or PTB7:PCBM layer, and spray coating a silver layer onto the PEDOT:PSS-based hole transport layer. In such process, the PEDOT:PSS-based hole transport layer is spray coated using a formulation that is different than the formulation used to spray coat the PEDOT:PSS PH1000 layer, wherein the formulation used to spray coat the PEDOT:PSS-based layer exhibits better wettability on P3HT:PCBM or PTB7:PCBM layers than the formulation used to spray coat the PEDOT:PSS PH1000 layer. The process may further comprise spray coating an optional titanium layer or a chromium layer onto the PEDOT:PSS PH1000 layer, and spray coating the metal oxide nanoparticle and/or PEIE layers onto the titanium or chromium layer. The process may also further comprise spray coating an outer protective barrier layer onto the silver layer. This example process produces a fully-sprayed photovoltaic system comprising an at least partially transparent silver anode, a PEDOT:PSS-based hole transport layer, a P3HT:PCBM or PTB7:PCBM bulk heterojunction active layer, and a PEDOT:PSS PH1000 cathode having a lower work function than the silver anode resulting from the metal oxide nanoparticle and/or PEIE layers located between and contacting the P3HT:PCBM or PTB7:PCBM bulk heterojunction active layer and the PEDOT:PSS PH1000 cathode (or the optional titanium or chromium electron transport layer).

Another process according to the present invention for producing a fully-sprayed photovoltaic system comprises spray coating a dielectric layer onto a substrate, spray coating a layer of dielectric material comprising metallic particles (e.g., silver-coated copper particles) embedded in the dielectric material onto the dielectric layer, spray coating metal oxide nanoparticle and/or PEIE layers onto the metallic particle-containing dielectric layer, spray coating a P3HT:PCBM layer or a PTB7:PCBM layer onto the PEIE layer, spray coating a PEDOT:PSS-based hole transport layer onto the P3HT:PCBM or PTB7:PCBM layer, and spray coating one of a silver layer onto the PEDOT:PSS-based hole transport layer, or a PEDOT:PSS PH1000 layer onto the PEDOT:PSS-based layer. Also, according to the present invention, a separate PEDOT:PSS-based hole transport layer may be omitted and a PEDOT:PSS-based layer may be spray coated onto the P3HT:PCBM or PTB7:PCBM layer. The process may further comprise spray coating an optional titanium layer or a chromium layer onto the metallic particle-containing dielectric layer, and spray coating the metal oxide nanoparticle and/or PEIE layers onto the titanium or chromium layer. The process may also further comprise spray coating an outer protective barrier layer onto the layer stack. This example process produces a fully-sprayed photovoltaic system comprising an at least partially transparent anode, a PEDOT:PSS-based hole transport layer, a P3HT:PCBM or PTB7:PCBM bulk heterojunction active layer, and a metallic particle-containing cathode having a lower work function than the anode resulting from the metal oxide nanoparticle and/or PEIE layers located between and contacting the P3HT:PCBM or PTB7:PCBM bulk heterojunction active layer and the cathode (or the optional titanium or chromium electron transport layer).

Another preferred process according to the present invention for producing a fully-sprayed photovoltaic system comprises spray coating a dielectric layer onto a substrate. One of a layer of dielectric material comprising metallic particles (e.g., silver-coated copper particles) embedded in the dielectric material, a silver layer, or a PEDOT:PSS PH1000 layer may be spray coated onto the dielectric layer to form a cathode layer. Metal oxide nanoparticle and/or PEIE layers are then spray coated onto the cathode layer. A P3HT:PCBM layer or a PTB7:PCBM layer is then spray coated onto the PEIE layer. A PEDOT:PSS-based hole transport layer may optionally be spray coated onto the P3HT:PCBM or PTB7:PCBM layer. A layer comprising a blend of A-PEDOT:PSS and PEDOT:PSS CPP may be spray coated onto the P3HT:PCBM or PTB7:PCBM layer to form an anode layer. The process may further comprise spray coating an optional titanium layer or a chromium layer onto the metallic particle-containing dielectric layer, and spray coating the metal oxide nanoparticle and/or PEIE layers onto the titanium or chromium layer. The process may also further comprise spray coating an outer protective barrier layer onto the layer stack.

A further preferred example of a process according to the present invention for producing a fully-sprayed photovoltaic system comprises spray coating a dielectric layer onto a substrate, spray coating a first silver layer onto the dielectric layer, spray coating metal oxide nanoparticle and/or PEIE layers onto the first silver layer, spray coating a P3HT:PCBM layer or a PTB7:PCBM layer onto the PEIE layer, spray coating a PEDOT:PSS-based layer onto the P3HT:PCBM layer or PTB7:PCBM layer, and spray coating a second silver layer onto the PEDOT:PSS-based layer. The PEDOT:PSS-based layer may comprise a PEDOT:PSS CPP layer, a PEDOT:PSS PH1000 layer, an A-PEDOT:PSS layer, or a layer comprising a blend of any two or all three of PEDOT:PSS CPP, A-PEDOT:PSS, and PEDOT:PSS PH1000. The process may also further comprise spray coating an outer protective barrier layer onto the second silver layer. This example process produces a fully-sprayed photovoltaic system comprising an at least partially transparent hybrid bi-layer anode (comprising a silver layer and a PEDOT:PSS-based layer), a P3HT:PCBM or PTB7:PCBM bulk heterojunction active layer, and a silver cathode layer having a lower work function than the anode resulting from the metal oxide nanoparticle and/or PEIE layers located between and contacting the P3HT:PCBM or PTB7:PCBM bulk heterojunction active layer and the silver cathode layer.

Another preferred process according to the present invention for producing a fully-sprayed photovoltaic system comprises spray coating a dielectric layer onto a substrate, spray coating a first silver layer onto the dielectric layer, spray coating metal oxide nanoparticle and/or PEIE layers onto the first silver layer, spray coating a P3HT:PCBM layer or a PTB7:PCBM layer onto the PEIE layer, spray coating an inorganic hole transport layer (e.g., a layer comprising graphene, carbon nanotubes, or MoO₃) onto the P3HT:PCBM layer or PTB7:PCBM layer, and spray coating a second silver layer onto the inorganic hole transport layer. The process may also further comprise spray coating an outer protective barrier layer onto the second silver layer. This example process produces a fully-sprayed photovoltaic system comprising an at least partially transparent silver anode layer, an inorganic hole transport layer, a P3HT:PCBM or PTB7:PCBM bulk heterojunction active layer, and a silver cathode layer having a lower work function than the silver anode layer resulting from the metal oxide nanoparticle and/or PEIE layers located between and contacting the P3HT:PCBM or PTB7:PCBM bulk heterojunction active layer and the silver cathode layer.

Another preferred example of a process according to the present invention for producing a fully-sprayed photovoltaic system comprises spray coating a dielectric layer onto a substrate, spray coating a silver layer onto the dielectric layer, spray coating metal oxide nanoparticle and/or PEIE layers onto the silver layer, spray coating a P3HT:PCBM layer or a PTB7:PCBM layer onto the PEIE layer, spray coating an inorganic hole transport layer (e.g., a layer comprising graphene, carbon nanotubes, or MoO₃) onto the P3HT:PCBM layer or PTB7:PCBM layer, and spray coating a PEDOT:PSS-based layer onto the inorganic hole transport layer. The PEDOT:PSS-based layer may comprise a PEDOT:PSS CPP layer, a PEDOT:PSS PH1000 layer, an A-PEDOT:PSS layer, or a layer comprising a blend of any two or all three of PEDOT:PSS CPP, A-PEDOT:PSS, and PEDOT:PSS PH1000. The process may also further comprise spray coating an outer protective barrier layer onto the PEDOT:PSS-based layer. This example process produces a fully-sprayed photovoltaic system comprising an at least partially transparent PEDOT:PSS-based anode layer, an inorganic hole transport layer, a P3HT:PCBM or PTB7:PCBM bulk heterojunction active layer, and a silver cathode layer having a lower work function than the PEDOT:PSS-based anode layer resulting from the metal oxide nanoparticle and/or PEIE layers located between and contacting the P3HT:PCBM or PTB7:PCBM bulk heterojunction active layer and the silver cathode layer.

Another preferred process according to the present invention for producing a fully-sprayed photovoltaic system comprises spray coating a dielectric layer onto a substrate, spray coating a first silver layer onto the dielectric layer, spray coating metal oxide nanoparticle and/or PEIE layers onto the first silver layer, spray coating a P3HT:PCBM layer or a PTB7:PCBM layer onto the PEIE layer, spray coating an inorganic hole transport layer (e.g., a layer comprising graphene, carbon nanotubes, or MoO₃) onto the P3HT:PCBM layer or PTB7:PCBM layer, spray coating a PEDOT:PSS-based layer onto the inorganic hole transport layer, and spray coating a second silver layer onto the PEDOT:PSS-based layer. The PEDOT:PSS-based layer may comprise a PEDOT:PSS CPP layer, a PEDOT:PSS PH1000 layer, an A-PEDOT:PSS layer, or a layer comprising a blend of any two or all three of PEDOT:PSS CPP, A-PEDOT:PSS, and PEDOT:PSS PH1000. The process may also further comprise spray coating an outer protective barrier layer onto the second silver layer. This example process produces a fully-sprayed photovoltaic system comprising an at least partially transparent hybrid bi-layer anode (comprising a silver layer and a PEDOT:PSS-based layer), an inorganic hole transport layer, a P3HT:PCBM or PTB7:PCBM bulk heterojunction active layer, and a silver cathode layer having a lower work function than the anode layer resulting from the metal oxide nanoparticle and/or PEIE layers located between and contacting the P3HT:PCBM or PTB7:PCBM bulk heterojunction active layer and the silver cathode layer.

The fully-sprayed photovoltaic systems described herein may achieve a photovoltaic efficiency (η) of at least 0.1%, at least 0.5%, at least 1%, at least 1.5%, at least 2%, at least 2.5%, at least 3%, at least 3.5%, at least 4%, at least 4.5%, or at least 5%.

The examples that follow are intended to further describe some aspects of the systems and processes according to the present invention.

### EXAMPLES

### Example-1

A fully-sprayed photovoltaic system was prepared comprising a partially transparent PEDOT:PSS PH1000 anode, a PEDOT:PSS CPP hole transport layer, a P3HT:PCBM bulk heterojunction active layer, and a PEDOT:PSS PH1000 cathode having a lower work function than the PEDOT:PSS PH1000 anode resulting from a PEIE layer located between and contacting the P3HT:PCBM bulk heterojunction active layer and the PEDOT:PSS PH1000 cathode. The multi-layer structure was spray coated onto a glass slide (Forlab, 26×76 mm, thickness 1 mm). The photoactive area of the photovoltaic system was 25 mm×25 mm. A PEDOT:PSS PH1000 formulation (Heraeus) modified with 6% ethylene glycol was spray coated onto the glass slide at a thickness of 180-230 nanometers to form a cathode layer. The spray coating parameters for the deposition of the PEDOT:PSS PH1000 cathode layer are reported in the Table 1.

TABLE 1

| Time of spray | 120 | sec. |
|---|---|---|
| Substrate temperature | 100° | C. |
| Airbrush distance from substrate | 13 | cm |
| Nozzle regulation | <240° | |
| Gas pressure (AIR) | 1 | bar |

After the deposition of the PEDOT:PSS PH1000 layer, the coated glass slides were thermally annealed at 120° C. for 30 minutes on a hotplate in ambient air.

A PEIE (Sigma-Aldrich) layer was then spray coated onto the PEDOT:PSS PH1000 cathode layer at a thickness of 10-30 nanometers. The PEIE was diluted to a concentration of 0.4% by weight in deionized water and then spray coated using the parameters reported in Table 2.

TABLE 2

| Time of spray | 5 | sec. |
|---|---|---|
| Substrate temperature | 50° | C. |
| Airbrush distance from substrate | 10 | cm |
| Nozzle regulation | 30° (minimum) | |
| Gas pressure (AIR) | 1 | bar |

After the deposition of the PEIE layer, the coated glass slides were thermally annealed at 120° C. for 10 minutes on a hotplate in ambient air.

A P3HT:PCBM active layer was then spray coated onto the PEIE layer at a thickness of 200-220 nanometers. The active material blend was prepared from a mixture of P3HT (Rieke Metals) and PCBM (Solenne BV) at a weight ratio of 1:0.7 (P3HT:PCBM). The blend was dissolved in ortho-dichlorobenzene (Sigma-Aldrich) at 2% by weight, diluted five times in chlorobenzene (Sigma-Aldrich), and then spray coated using the parameters reported in Table 3.

TABLE 3

| Time of spray | 3 spray passes, 13 sec./pass | |
|---|---|---|
| Substrate temperature | 40° | C. |
| Airbrush distance from substrate | 16 | cm |
| Nozzle regulation | 90° | |
| Gas pressure (NITROGEN) | 1 | bar |

After the deposition of the P3HT:PCBM active layer, the coated glass slides were thermally annealed at 120° C. for 120 minutes on a hotplate in ambient air.

A PEDOT:PSS CPP (Clevios Heraeus) hole transport layer was then spray coated onto the P3HT:PCBM active layer at a thickness of 90-100 nanometers. The PEDOT:PSS CPP formulation obtained from the manufacturer was modified with 5% dimethyl sulfoxide (DMSO), diluted six times in isopropyl alcohol, and then spray coated using the parameters reported in Table 4.

TABLE 4

| Time of spray | 30 | sec. |
|---|---|---|
| Substrate temperature | 80° | C. |
| Airbrush distance from substrate | 13 | cm |
| Nozzle regulation | 180° | |
| Gas pressure (AIR) | 1 | bar |

After the deposition of the PEDOT:PSS CPP hole transport layer, the coated glass slides were thermally annealed at 120° C. for 2 minutes on a hotplate in ambient air.

A PEDOT:PSS PH1000 formulation (Heraeus) modified with 6% ethylene glycol was then spray coated onto the PEDOT:PSS CPP hole transport layer at a thickness of 160-180 nanometers to form an anode layer. The spray coating parameters for the deposition of the PEDOT:PSS PH1000 anode layer are reported in the Table 5.

TABLE 5

| Time of spray | 60 | sec. |
|---|---|---|
| Substrate temperature | 100° | C. |
| Airbrush distance from substrate | 13 | cm |
| Nozzle regulation | 225° | |
| Gas pressure (AIR) | 1 | bar |

After the deposition of the PEDOT:PSS PH1000 anode layer, the coated glass slides were thermally annealed at 120° C. for 3 minutes on a hotplate in ambient air.

The resulting coated glass slides were tested for open circuit voltage (Voc), short circuit current density (Jsc), fill factor (FF), and efficiency (η). The results are reported in Table 6.

TABLE 6

| | |
|---|---|
| Voc (mV) | 205 |
| Jsc (mA/cm2) | 0.6 |
| FF (%) | 24 |
| η (%) | 0.03 |

### Example-2

A fully-sprayed photovoltaic system was prepared comprising a partially transparent PEDOT:PSS PH1000 anode, a PEDOT:PSS CPP hole transport layer, a P3HT:PCBM bulk heterojunction active layer, and a silver cathode having a lower work function than the PEDOT:PSS PH1000 anode resulting from a PEIE layer located between and contacting the P3HT:PCBM bulk heterojunction active layer and the silver cathode. The multi-layer structure was spray coated onto a glass slide (Forlab, 26×76 mm, thickness 1 mm). The photoactive area of the photovoltaic system was 25 mm×25 mm. The silver cathode was spray coated on the glass slide to a thickness of about 60 nanometers using a Tollens' reaction and a dual spray gun.

A PEIE (Sigma-Aldrich) layer was then spray coated onto the silver cathode layer at a thickness of 10-30 nanometers. The PEIE was diluted to a concentration of 0.4% by weight in deionized water and then spray coated using the parameters reported in Table 7.

TABLE 7

| Time of spray | 5 | sec. |
|---|---|---|
| Substrate temperature | 50° | C. |
| Airbrush distance from substrate | 10 | cm |
| Nozzle regulation | 30° (minimum) | |
| Gas pressure (AIR) | 1 | bar |

After the deposition of the PEIE layer, the coated glass substrates were thermally annealed at 120° C. for 10 minutes on a hotplate in ambient air.

A P3HT:PCBM active layer was then spray coated onto the PEIE layer at a thickness of 200-220 nanometers. The active material blend was prepared from a mixture of P3HT (Rieke Metals) and PCBM (Solenne BV) at a weight ratio of 1:0.7 (P3HT:PCBM). The blend was dissolved in ortho-dichlorobenzene (Sigma-Aldrich) at 2% by weight, diluted five times in chlorobenzene (Sigma-Aldrich), and then spray coated using the parameters reported in Table 8.

TABLE 8

| Time of spray | 3 spray passes, 13 sec./pass | |
|---|---|---|
| Substrate temperature | 40° | C. |
| Airbrush distance from substrate | 16 | cm |
| Nozzle regulation | 90° | |
| Gas pressure (NITROGEN) | 1 | bar |

After the deposition of the P3HT:PCBM active layer, the coated glass substrates were thermally annealed at 120° C. for 120 minutes on a hotplate in ambient air.

A PEDOT:PSS CPP (Clevios Heraeus) hole transport layer was then spray coated onto the P3HT:PCBM active layer at a thickness of 90-100 nanometers. The PEDOT:PSS CPP formulation obtained from the manufacturer was modified with 5% dimethyl sulfoxide (DMSO), diluted six times in isopropyl alcohol, and then spray coated using the parameters reported in Table 9.

TABLE 9

| Time of spray | 30 | sec. |
|---|---|---|
| Substrate temperature | 80° | C. |
| Airbrush distance from substrate | 13 | cm |
| Nozzle regulation | 180° | |
| Gas pressure (AIR) | 1 | bar |

After the deposition of the PEDOT:PSS CPP hole transport layer, the coated glass substrates were thermally annealed at 120° C. for 2 minutes on a hotplate in ambient air.

A PEDOT:PSS PH1000 formulation (Heraeus) modified with 6% ethylene glycol was spray coated onto the PEDOT:PSS CPP hole transport layer at a thickness of 160-180 nanometers to form an anode layer. The spray coating parameters for the deposition of the PEDOT:PSS PH1000 anode layer are reported in the Table 10.

TABLE 10

| Time of spray | 60 | sec. |
|---|---|---|
| Substrate temperature | 100° | C. |
| Airbrush distance from substrate | 13 | cm |
| Nozzle regulation | 225° | |
| Gas pressure (AIR) | 1 | bar |

After the deposition of the PEDOT:PSS PH1000 anode layer, the coated glass substrates were thermally annealed at 150° C. for 1 minute on a hotplate in ambient air.

The resulting constructs were tested for open circuit voltage (Voc), short circuit current density (Jsc), fill factor (FF), and efficiency (η). The results are reported in Table 11.

TABLE 11

| | |
|---|---|
| Voc (mV) | 142 |
| Jsc (mA/cm2) | 2.3 |
| FF (%) | 25 |
| η (%) | 0.1 |

### Example-3

A fully-sprayed photovoltaic system was prepared comprising a partially transparent PEDOT:PSS PH1000 anode, a PEDOT:PSS CPP hole transport layer, a P3HT:PCBM bulk heterojunction active layer, and a silver cathode having a lower work function than the PEDOT:PSS PH1000 anode resulting from a PEIE layer located between and contacting the P3HT:PCBM bulk heterojunction active layer and the silver cathode. The multi-layer structure was spray coated onto a glass slide (Forlab, 26×76 mm, thickness 1 mm). The photoactive area of the photovoltaic system was 25 mm×25 mm. The silver cathode was spray coated on the glass slide to a thickness of about 60 nanometers using a Tollens' reaction and a dual spray gun.

A PEIE (Sigma-Aldrich) layer was then spray coated onto the silver cathode layer at a thickness of 10-30 nanometers. The PEIE was diluted to a concentration of 5% by weight in deionized water and then spray coated using the parameters reported in Table 12.

TABLE 12

| Time of spray | 5 | sec. |
|---|---|---|
| Substrate temperature | 100° | C. |
| Airbrush distance from substrate | 10 | cm |
| Nozzle regulation | 30° (minimum) | |
| Gas pressure (AIR) | 1 | bar |

After the deposition of the PEIE layer, the coated glass substrates were thermally annealed at 120° C. for 10 minutes on a hotplate in ambient air.

A P3HT:PCBM active layer was then spray coated onto the PEIE layer at a thickness of 200-220 nanometers. The active material blend was prepared from a mixture of P3HT (Rieke Metals) and PCBM (Solenne BV) at a weight ratio of 1:0.7 (P3HT:PCBM). The blend was dissolved in ortho-dichlorobenzene (Sigma-Aldrich) at 2% by weight, diluted five times in chlorobenzene (Sigma-Aldrich), and then spray coated using the parameters reported in Table 13.

TABLE 13

| Time of spray | 3 spray passes, 13 sec./pass | |
|---|---|---|
| Substrate temperature | 40° | C. |
| Airbrush distance from substrate | 16 | cm |
| Nozzle regulation | 90° | |
| Gas pressure (NITROGEN) | 1 | bar |

After the deposition of the P3HT:PCBM active layer, the coated glass substrates were thermally annealed at 120° C. for 120 minutes on a hotplate in ambient air.

A PEDOT:PSS CPP (Clevios Heraeus) layer was then spray coated onto the P3HT:PCBM active layer at a thickness of 90-100 nanometers. The PEDOT:PSS CPP formulation obtained from the manufacturer was modified with 5% dimethyl sulfoxide (DMSO), diluted six times in isopropyl alcohol, and then spray coated using the parameters reported in Table 14.

TABLE 14

| Time of spray | 30 | sec. |
|---|---|---|
| Substrate temperature | 80° | C. |
| Airbrush distance from substrate | 13 | cm |
| Nozzle regulation | 180° | |
| Gas pressure (AIR) | 1 | bar |

After the deposition of the PEDOT:PSS CPP layer, the coated glass substrates were thermally annealed at 120° C. for 2 minutes on a hotplate in ambient air.

A PEDOT:PSS PH1000 formulation (Heraeus) modified with 6% ethylene glycol was spray coated onto the PEDOT:PSS CPP layer at a thickness of 160-180 nanometers to form an anode layer. The spray coating parameters for the deposition of the PEDOT:PSS PH1000 anode layer are reported in the Table 15.

TABLE 15

| Time of spray | 60 | sec. |
|---|---|---|
| Substrate temperature | 100° | C. |
| Airbrush distance from substrate | 13 | cm |
| Nozzle regulation | 225° | |
| Gas pressure (AIR) | 1 | bar |

After the deposition of the PEDOT:PSS PH1000 anode layer, the coated glass substrates were thermally annealed at 150° C. for 1 minute on a hotplate in ambient air.

The resulting constructs were tested for open circuit voltage (Voc), short circuit current density (Jsc), fill factor (FF), and efficiency (η). The results are reported in Table 16.

TABLE 16

| | |
|---|---|
| Voc (mV) | 206 |
| Jsc (mA/cm2) | 7.8 |
| FF (%) | 27 |
| η (%) | 0.44 |

### Example-4

A fully-sprayed photovoltaic system was prepared comprising an anode layer comprising a blend of anhydrous PEDOT:PSS and PEDOT:PSS CPP, a PTB7:PCBM bulk heterojunction active layer, and a silver cathode layer having a lower work function than the PEDOT:PSS-based anode layer resulting from a zinc oxide nanoparticle layer sprayed on the silver cathode layer and a sprayed PEIE layer located between and contacting the PTB7:PCBM bulk heterojunction active layer and the zinc oxide nanoparticle layer. The multi-layer structure was spray coated onto a glass slide. The silver cathode layer was spray coated onto the glass slide to a thickness of about 60 nanometers using a Tollens' reaction and a dual spray gun. The zinc oxide nanoparticle layer was spray coated onto the silver cathode layer to a thickness of about 12-15 nanometers. The PEIE layer was spray coated onto the zinc oxide nanoparticle layer at a thickness of 12-15 nanometers. The PTB7:PCBM active layer was spray coated onto the PEIE layer at a thickness of 200-220 nanometers. The PEDOT:PSS-based anode layer was spray coated onto the P3HT:PCBM active layer at a thickness of 90-100 nanometers. The layers were spray coated and processed similar to the layers described above in Examples 1-3. The resulting constructs (n=4) were tested for open circuit voltage (Voc), short circuit current density (Jsc), fill factor (FF), and efficiency (η). The results are reported in Table 17.

TABLE 17

| | | Standard | | | |
|---|---|---|---|---|---|
| | Mean | Deviation | Minimum | Median | Maximum |
| Voc (mV) | 0.24 | 0.04 | 0.12 | 0.26 | 0.33 |
| Jsc (mA/cm2) | 6.10 | 0.76 | 4.2 | 6.15 | 7.89 |
| FF (%) | 27.40 | 2.36 | 21.71 | 27.33 | 33.21 |
| η (%) | 0.45 | 0.13 | 0.11 | 0.48 | 0.73 |

### Example-5

A partially-sprayed photovoltaic system was prepared comprising a silver anode layer, a molybdenum trioxide hole transport layer, a PTB7:PCBM bulk heterojunction active layer, an electron transport layer comprising a PEIE layer contacting the PTB7:PCBM bulk heterojunction active layer and a zinc oxide nanoparticle layer contacting the PEIE layer, and an indium tin oxide (ITO) cathode layer. The multi-layer structure was produced by spray coating a zinc oxide nanoparticle dispersion (Genes'Ink SZ11034) under ambient conditions onto an ITO-coated glass substrate (Kintec Company, sheet resistance of 15 Ohm-per-square) at a substrate temperature of 120° C. After spray coating the zinc oxide nanoparticle layer, the construct was heated at 120° C. for 10 minutes in air. Thereafter, a PEIE solution (80% ethoxylated, 70,000 grams-per-mole weight average molecular weight, diluted with ethanol to a contraception of 0.1 weight percent from an aqueous stock solution of 35-40 weight percent from Sigma Aldrich) was spray coated onto the previously spray coated zinc oxide nanoparticle layer at a substrate temperature of 80° C. After spray coating the PEIE layer, the construct was heated at 120° C. for 10 minutes in air. Thereafter, a solution of PTB7 (Solarmer) and PCBM (Solenne BV) in ortho-xylene with 3% v/v of 1,8-diiodooctane was spray coated onto the previously spray coated PEIE layer at a substrate temperature of 70° C. After spray coating the PTB7:PCBM active material layer, the construct was held under low vacuum (10⁻¹ mbar) for 20 minutes. Thereafter, the molybdenum trioxide hole transport layer and the silver anode layer were respectively deposited by evaporation deposition in vacuum (10⁻⁷ mbar). The resulting constructs (n=6) were tested for open circuit voltage (Voc), short circuit current density (Jsc), fill factor (FF), and efficiency (η). The results are reported in Table 18.

TABLE 18

| | | Standard | | | |
|---|---|---|---|---|---|
| | Mean | Deviation | Minimum | Median | Maximum |
| Voc (mV) | 0.59 | 0.04 | 0.47 | 0.56 | 0.69 |
| Jsc (mA/cm2) | 13.28 | 0.84 | 10.74 | 12.73 | 15.19 |
| FF (%) | 47.25 | 2.72 | 41.55 | 45.46 | 54.26 |
| η (%) | 3.79 | 0.60 | 2.09 | 3.33 | 5.53 |

### Example-6

A partially-sprayed photovoltaic system was prepared comprising a PEDOT:PSS-based anode layer, a PTB7:PCBM bulk heterojunction active layer, an electron transport layer comprising a PEIE layer contacting the PTB7:PCBM bulk heterojunction active layer and a zinc oxide nanoparticle layer contacting the PEIE layer, and an indium tin oxide (ITO) cathode layer. The multi-layer structure was produced by spray coating a zinc oxide nanoparticle dispersion (Genes'Ink SZ11034) under ambient conditions onto an ITO-coated glass substrate (Kintec Company, sheet resistance of 15 Ohm-per-square) at a substrate temperature of 120° C. After spray coating the zinc oxide nanoparticle layer, the construct was heated at 120° C. for 10 minutes in air. Thereafter, a PEIE solution (80% ethoxylated, 70,000 grams-per-mole weight average molecular weight, diluted with ethanol to a contraception of 0.1 weight percent from an aqueous stock solution of 35-40 weight percent from Sigma Aldrich) was spray coated onto the previously spray coated zinc oxide nanoparticle layer at a substrate temperature of 80° C. After spray coating the PEIE layer, the construct was heated at 120° C. for 10 minutes in air. Thereafter, a solution of PTB7 (Solarmer) and PCBM (Solenne BV) in ortho-xylene with 3% v/v of 1,8-diiodooctane was spray coated onto the previously spray coated PEIE layer at a substrate temperature of 70° C. After spray coating the PTB7:PCBM active material layer, the construct was held under low vacuum (10⁻¹ mbar) for 20 minutes. Thereafter, a PEDOT:PSS solution (a 1:5 weight ratio blend of PEDOT:PSS CPP (105 D PEDOT:PSS, Haereus, modified with dimethylsulfoxide) and anhydrous PEDOT:PSS (dry pellets, Sigma Aldrich, dispersed in a mixture of 2-propanol, ethanol, and ethylene glycol)) was spray coated onto the preciously spay coated active material layer at a substrate temperature of 90° C. After spray coating the layer comprising PEDOT:PSS CPP and A-PEDOT:PSS, the construct was heated at 100° C. for 2 minutes in air. The resulting constructs (n=14) were tested for open circuit voltage (Voc), short circuit current density (Jsc), fill factor (FF), and efficiency (η). The results are reported in Table 19.

TABLE 19

| | | Standard | | | |
|---|---|---|---|---|---|
| | Mean | Deviation | Minimum | Median | Maximum |
| Voc (mV) | 0.68 | 0.01 | 0.57 | 0.70 | 0.74 |
| Jsc (mA/cm2) | 12.84 | 1.33 | 2.11 | 12.70 | 19.99 |
| FF (%) | 29.79 | 1.43 | 23.72 | 27.53 | 39.62 |
| η (%) | 2.63 | 0.30 | 0.38 | 2.66 | 4.31 |

### Example-7

A fully-sprayed photovoltaic system was prepared comprising an anhydrous PEDOT:PSS anode layer, a vanadium oxide (V₂O₅) hole transport layer, a PTB7:PCBM bulk heterojunction active layer, and a silver cathode layer having a lower work function than the anhydrous PEDOT:PSS anode layer resulting from a zinc oxide nanoparticle layer sprayed on the silver cathode layer and a sprayed PEIE layer located between and contacting the PTB7:PCBM bulk heterojunction active layer and the zinc oxide nanoparticle layer. The multi-layer structure was spray coated onto a glass slide. The silver cathode layer was spray coated onto the glass slide using a Tollens' reaction and a dual spray gun. The zinc oxide nanoparticle layer was spray coated onto the silver cathode layer. The PEIE layer was spray coated onto the zinc oxide nanoparticle layer. The PTB7:PCBM active layer was spray coated onto the PEIE layer. The layers were spray coated and processed similar to the layers described above in Examples 1-6.

The vanadium oxide hole transport layer was spray coated onto the P3HT:PCBM active layer using an aqueous solution of vanadium oxytriisopropoxide at a substrate temperature of 30° C., a spraying pressure of 2 bars, and a spraying distance of 15 centimeters. The sprayed vanadium oxytriisopropoxide solution was heated at 80° C. for 10 minutes to oxidize the vanadium and form the V₂O₅.

The anhydrous PEDOT:PSS anode layer was spray coated onto the vanadium oxide hole transport layer at substrate temperature of 80° C., a spraying pressure of 2 bars, a spraying distance of 15 centimeters, and using an anhydrous PEDOT:PSS solution. The sprayed anhydrous PEDOT:PSS solution was heated at 120° C. for 2 minutes. The anhydrous PEDOT:PSS solution was prepared by dry ball milling 100 milligrams of ORGACON™ Dry PEDOT:PSS solid pellets with approximately 5 millimeter diameter glass spheres, adding 12 milliliters of isopropanol and 253 microliters of ethanol to the dry milled material and wet milling, mixing 720 microliter of ethylene glycol into the wet milled material, and further dispersing the resulting anhydrous PEDOT:PSS solution in 12 milliliters of isopropanol.

The resulting constructs (n=8) were tested for open circuit voltage (Voc) and efficiency (η). The results are reported in Table 20.

TABLE 20

| | Median | Maximum |
|---|---|---|
| Voc (mV) | 0.46 | 0.49 |
| η (%) | 0.76 | 1.01 |

In the context of the present invention, certain layers and/or other components are referred to as being “adjacent,” applied “over,” or applied “onto” another layer or substrate. In this regard, it is contemplated that “adjacent,” “over,” and “onto” are used as relative terms to describe the relative positioning of layers and the like comprising a photovoltaic system. It is contemplated that one layer or other component may be either directly positioned or indirectly positioned beside another adjacent layer or other component. In aspects where one layer or other component is indirectly positioned beside another layer or other component, it is contemplated that additional intervening layers or other components may be positioned in between adjacent layers or components. Accordingly, and by way of example, where a first layer is said to be positioned adjacent to a second layer, applied over a second layer, or applied onto a second layer, it is contemplated that the first layer may be, but is not necessarily, directly beside and adhered to the second layer. Applicant reserves the right to amend the claims to explicitly recite “directly adjacent,” “directly over,” or “directly onto” in order to expressly indicate direct physical contact between two layers.

Some aspects have been described and illustrated in this specification to provide an overall understanding of the function, operation, and implementation of the disclosed processes and systems. It is understood that the some aspects described and/or illustrated in this specification can be combined with various other aspects. Such modifications and variations are intended to be included within the scope of this specification. As such, the claims can be amended to recite, in any combination, any aspects expressly or inherently described in, or otherwise expressly or inherently supported by, this specification. Further, Applicant reserves the right to amend the claims to affirmatively disclaim aspects that may be present in the prior art, even if those aspects are not expressly described in this specification. Therefore, any such amendments comply with written description and sufficiency requirements. The methods, systems, and devices disclosed and described in this specification can comprise, consist of, or consist essentially of the some aspects described herein.

Also, any numerical range recited in this specification is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Accordingly, Applicant reserves the right to amend this specification, including the claims, to expressly recite any sub-range of the same numerical precision subsumed within the ranges expressly recited herein. All such ranges are intended to be inherently described in this specification such that amending to expressly recite any such sub-ranges would comply with written description and sufficiency requirements. Additionally, numerical parameters described in this specification should be construed in light of the number of reported significant digits and by applying ordinary rounding techniques. It is also understood that numerical parameters described in this specification will necessarily possess the inherent variability characteristic of the underlying measurement techniques used to determine the numerical value of the parameter.

Any patent, publication, or other disclosure material identified herein is incorporated by reference into this specification in its entirety unless otherwise indicated, but only to the extent that the incorporated material does not conflict with existing descriptions, definitions, statements, or other disclosure material expressly set forth in this specification. As such, and to the extent necessary, the express disclosure as set forth in this specification supersedes any conflicting material incorporated by reference. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicants reserve the right to amend this specification to expressly recite any subject matter, or portion thereof, incorporated by reference herein.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a component” means one or more components, and thus, possibly, more than one component is contemplated and can be employed or used in an implementation of the described methods, systems, and devices. Further, the use of a singular noun includes the plural, and the use of a plural noun includes the singular, unless the context of the usage requires otherwise.

What is claimed is:

1. A process for producing a photovoltaic system comprising:
depositing a first electrode layer over a substrate;
spray coating an ethoxylated polyethyleneimine (PEIE) layer over the first electrode layer;
depositing a bulk heterojunction active layer over the PEIE layer; and
depositing a second electrode layer over the bulk heterojunction active layer.

2. The process of claim 1, further comprising spray coating a metal oxide nanoparticle layer over the first electrode layer, wherein the PEIE layer is spray coated onto the metal oxide nanoparticle layer.

3. The process of claim 2, wherein the metal oxide nanoparticle layer comprises zinc oxide nanoparticles.

4. The process of claim 1, further comprising:
spray coating a dielectric layer over the substrate; and
spray coating the first electrode layer over the dielectric layer.

5. The process of claim 4, wherein the dielectric layer comprises a cured acrylic urethane clear-coat layer having a surface roughness (Ra) of less than 25 nanometers.

6. The process of claim 1, wherein depositing the second electrode layer over the bulk heterojunction active layer comprises spray coating a formulation comprising anhydrous poly(3,4-ethylenedioxythiophene):poly(styrene sulfonate) (PEDOT:PSS).

7. The process of claim 1, wherein depositing the bulk heterojunction active layer over the PEIE layer comprises spray coating a formulation comprising:
poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]]:[6,6]-phenyl C₆₁-butyric acid methyl ester (PTB7:PCBM); or
poly(3-hexyl thiophene):[6,6]-phenyl C₆₁-butyric acid methyl ester (P3HT:PCBM).

8. The process of claim 1, wherein:
the first electrode layer comprises:
a spray coated silver layer; or
a spray coated layer comprising PEDOT:PSS; and
the second electrode layer comprises:
a spray coated silver layer; or
a spray coated layer comprising PEDOT:PSS.

9. The process of claim 8, wherein the spray coated silver layers are formed from the reaction products of a Tollens' reaction.

10. The process of claim 8, wherein the spray coated layers comprising PEDOT:PSS are formed from a spray coated formulation comprising anhydrous PEDOT:PSS.

11. The process of claim 1, wherein the PEIE layer is spray coated using a formulation consisting of PEIE, water, and optionally ethanol, 2-propanol, or isopropanol, or any combination of ethanol, 2-propanol, or isopropanol.

12. A process for producing a low work function electrode for a photovoltaic system comprising:
depositing an electrode layer over a substrate; and
spray coating an ethoxylated polyethyleneimine (PEIE) layer over the electrode layer.

13. The process of claim 12, further comprising spray coating a metal oxide nanoparticle layer over the electrode layer, wherein the PEIE layer is spray coated onto the metal oxide nanoparticle layer.

14. The process of claim 13, wherein the metal oxide nanoparticle layer comprises zinc oxide nanoparticles.

15. The process of claim 12, further comprising:
spray coating a dielectric layer over the substrate; and
spray coating the first electrode layer over the dielectric layer.

16. The process of claim 15, wherein the dielectric layer comprises a cured acrylic urethane clear-coat layer having a surface roughness (Ra) of less than 25 nanometers.

17. The process of claim 12, wherein depositing the electrode layer comprises spray coating a silver layer over the substrate.

18. The process of claim 17, wherein the silver layer is formed from the reaction products of a Tollens' reaction.

19. The process of claim 12, wherein depositing the electrode layer comprises spray coating a formulation comprising PEDOT:PSS.

20. The process of claim 12, wherein the PEIE layer is spray coated using a formulation consisting of PEIE, water, and optionally ethanol, 2-propanol, or isopropanol, or any combination of ethanol, 2-propanol, or isopropanol.
